(19) United States
(12) Patent Application Publication
(10) Pub. No.: US 2005/0217716 A1
(43) Pub. Date: Oct. 6, 2005

(54) Photovoltaic power generation system

(75) Inventors: Hiroto Masuda, Higashiomi-shi (JP); Keiji Nakagawa, Higashiomi-shi (JP)

Correspondence Address: HOGAN & HARTSON L.L.P., 500 S. GRAND AVENUE, SUITE 1900, LOS ANGELES, CA, 90071-2611, US

(73) Assignee: KYOCERA CORPORATION

(21) Appl. No.: 11/046,201

(22) Filed: Jan. 27, 2005

(30) Foreign Application Priority Data
Jan. 29, 2004 (JP) 2004-021945
Mar. 29, 2004 (JP) 2004-094015
Jun. 23, 2004 (JP) 2004-185143
Jun. 29, 2004 (JP) 2004-191747
Jul. 28, 2004 (JP) 2004-219777

(51) Int. Cl. H01L 25/00

(52) U.S. Cl. 136/244

(57) ABSTRACT

A photovoltaic power generation system comprises: a rectangular- or square-shaped solar cell module M including one or more solar cell elements 5; first and second racks 101, 102 assembled to opposite sides of the solar cell module M, respectively; and a weight member 104 disposed at a predetermined place of the first rack 101 and/or the second rack 102. The system is adapted to be held to place by means of the weight member 104 in order that the solar cell module M may not be blown away by the wind. Therefore, the system may be used simply by placing the system on an installation surface such as a flat roof. This results in the reduction of the number of assembly steps involved in installation works and the reduction of fabrication costs and time. Thus is achieved cost reduction.

### BACKGROUND OF THE INVENTION

1. Field of the Invention

The present invention relates to a photovoltaic power generation system for generating photovoltaic power by using solar cell modules, and more particularly to a photovoltaic power generation system adapted to be rack mounted on a horizontal installation surface such as a flat roof.

The “solar cell module” means herein a panel-shaped device including one or more solar cell elements electrically interconnected in series and/or in parallel.

A unit adapted to generate power by using the solar cell module(s) is referred to as a “solar cell unit”.

A system adapted to output the photovoltaic power by using one solar cell unit or an assembly of the above solar cell units interconnected is referred to as a “photovoltaic power generation system”.

2. Description of the Related Art

Recently, the photovoltaic power generation systems have come into wide use, the system including the solar cell modules installed on a house roof or the like for outputting the photovoltaic power. In this connection, solar cell units adapted to a variety of roof configurations have been manufactured. In addition, there have been proposed installation methods for rooftop-mounting solar cell units, the methods arranged in various ways.

For instance, there is known a rooftop-unification solar cell module which is so fabricated as to be unified with the roof.

On the other hand, there has been proposed an installation method of a so-called rooftop-mounting system, the method including the steps of fabricating a rack on roof tiles, the rack including longitudinal bars and transverse bars; and installing the solar cell modules on the resultant rack.

However, the aforementioned installation method is basically designed to install the solar cell modules on an inclined roof. Accordingly, in a case where the photovoltaic power generation system is installed on a substantially flat house-roof, such as a roof of a building (hereinafter, such a house-roof will be referred to as a “flat roof”), incident solar radiation on the solar cell module has such a small incidence angle that the power output is normally 30% to 40% decreased.

As a solution to such a problem, a photovoltaic power generation system as shown in FIG. 48 has been proposed.

The figure is a perspective view showing a conventional photovoltaic power generation system installed on the flat roof. The photovoltaic power generation system is constructed such that the solar cell modules are supported slantwise. Accordingly, the system employs a rack to mount the solar cell modules slantwise.

The installation method for this photovoltaic power generation system is described as below.

First, anchors are buried by drilling holes in a concrete roof as a horizontal installation surface. A foot 61 to be secured to the anchor is formed from heavy material such as concrete. The foot 61 is fixed to place by means of an anchor bolt (not shown) driven into the roof.

Partly because of the weight thereof, the feet 61 are able to support the solar cell modules in a manner to ensure that the solar cell modules are not blown away by negative pressure load due to wind or the like.

Next, elongate base rails 64 formed of a metal member are mounted on the plural feet 61 as extended across these feet. Metal supports 63a to 63c are secured onto these base rails 64 and then, solar cell modules 62 are supportedly secured onto these metal supports 63.

The metal supports 63a to 63c have different heights, respectively. The metal support 63a, for example, has the smallest height. The height increases in the ascending order of the metal support 63a, the metal support 63b and the metal support 63c. This permits the solar cell modules 62 to be installed as inclined at a desired angle, thereby increasing the efficiency of the photovoltaic power generation.

In a case of installation in Japan, the inclination of the solar cell modules 62 is generally in the range of 30° to 45° in conjunction with the latitudes of Japan. In snowy areas and such, however, the solar cell modules may sometimes be inclined at 45° such as to increase an effect to allow roof-covering snow to fall by itself.

Unfortunately, the aforementioned prior art has a drawback that the foundation works extends the period of works.

Furthermore, the above method requires the fixing of anchors into the installation surface, which involves the drilling step to form the holes in the surface. The holes detrimentally allow the invasion of rain water therethrough so that the installation surface is damaged. As a result, the life of the installation surface is shortened.

What is more, the system includes a large number of components which take much time to assemble. In addition, the individual components are heavy so that the conveyance of the members up to the roof or the carriage of the members involves potential danger.

In the case of installation on an old building, an installation surface of the building is lowered in dead load. In order to obviate the breakdown of the building, therefore, care must be previously taken to determine a site where support posts are set and to bury the anchors in the site where the support posts are set.

In this case, the site where the anchors are buried does not necessarily provide such conditions as to permit the solar cell modules to be so directed as to provide a substantial power output. Hence, the solar cell modules may not be installed in an optimum direction and a lowered power output may result.

Furthermore, those components of the photovoltaic power generation system, which include the base rails, the metal supports, the concrete feet (molded articles with fixing members, such as base rails, embedded therein) and the like, are elongated and heavy articles, which occupy an extremely large area and volume of a truck box when transported. This results in an increased transportation cost.

In a case where a plurality of solar cell modules are laid out, the individual modules must be provided with ground connectors. This results in an increased cost for connection and requires a cumbersome work.

In a case where a plurality of solar cell units are interconnected, attention must be paid to an unevenness, a drainage angle, and joints of the installation surface. In a structure wherein the solar cell units are fixed to each other by means of bolts (commonly, M6 to M8), the fitting engagement of the solar cell units by means of bolts will become extremely difficult unless the solar cell units are positioned with precisions of about 3 to 6 mm.

It is an object of the invention to provide a photovoltaic power generation system which has a simplified structure to reduce the number of steps of the installation works and to reduce the fabrication costs and time, thereby achieving the cost reduction.

It is another object of the invention to provide a photovoltaic power generation system which may be installed without increasing the positioning precisions, which are required by the prior art.

It is still another object of the invention to provide a photovoltaic power generation system which reduces the transportation costs for components, thereby achieving the cost reduction.

It is still another object of the invention to provide a photovoltaic power generation system wherein a plurality of solar cell units are arranged in a manner to facilitate the ground connection.

It is still another object of the invention to provide a photovoltaic power generation system wherein a plurality of solar cell units are arranged in a simple manner.

### BRIEF SUMMARY OF THE INVENTION

According to the invention, a photovoltaic power generation system comprises: a rectangular- or square-shaped solar cell module including one or more solar cell elements; first and second racks assembled to opposite sides of the solar cell module, respectively; and a weight member disposed at a predetermined place of the first rack and/or the second rack.

According to the photovoltaic power generation system of the invention, the first and second racks are assembled to the opposite sides of a frame of the solar cell module. Subsequently, the resultant solar cell unit is installed on the installation surface while the weight members are placed on the first and/or the second rack.

By simply placing the solar cell units at place, the solar cell units are allowed to operate as the photovoltaic power generation system. In addition, the system negates the need for the anchor works on the installation surface such as the roof, or the foundation works. Thus are eliminated the drawbacks such as the invasion of rain water into the roof, which results from the foundation works. Hence, works for waterproofing the roof may be obviated.

In a case where the solar cell unit is installed on the flat roof, in particular, the unit forms an integrated rack-mounting photovoltaic power generation system fixed to place by the dead weight of the solar cell unit.

Since the photovoltaic power generation system of the invention does not require the anchor works on the installation surface such as the roof, a per-unit-area load on the installation surface is decreased. This results in a reduced load on the building. Hence, the system of the invention may also be installed on a building, on which the installation of the system was set aside due to the dead load problem. Thus, the system of the invention can find applications in wider fields or extend the range of use.

In addition, the number of components is notably reduced by using the weight member as a counterweight against wind load.

The photovoltaic power generation system of the invention is constructed such that the weight member is placed on the first rack and/or the second rack. This eliminates the restriction on the work procedure, so that the work efficiency is increased while the fabrication costs are reduced.

Furthermore, the system of the invention does not include a component serving as reference for the installation, nor require a marking operation. This leads to a remarkably shortened fabrication time. In addition, the system of the invention facilitates a partial disassembly thereof for removal of the system or for maintenance service. In a case where the photovoltaic power generation system comprises plural stages of solar cell arrays, the number of work steps in particular is dramatically reduced.

It is preferred that the first rack has a greater height than the second rack thereby to incline the solar cell module.

In this manner, the solar cell module may be installed as inclined at a desired angle of, say, 1° to 15° or 30° to 45°. Thus, the efficiency of the photovoltaic power generation is increased.

Since the works for burying the foundation in the roof are not necessary, the solar cell unit may be installed in a direction to receive a larger quantity of solar radiation or to generate a larger quantity of power. Thus is accomplished an efficient power generation.

It is preferred that the first rack and the second rack are each provided with a mounting member for insertion of the solar cell module.

The mounting member may include: a guide portion having a function as an insertion guide for the solar cell module; and a pair of bent portions folded inwardly for fixing the inserted solar cell module to inhibit the back-forth movement thereof.

This facilitates the positioning of the solar cell module with respect to the racks (such as alignment of screw holes) and hence, the assembly steps are simplified.

If the elasticity of the rack structure itself allows the guide portion to expand outwardly, the solar cell module may be mounted or dismounted without moving the rack. As a result, the constructability of the system is not lowered.

The pair of the bent portions of the first rack and/or the second rack is bent at an angle smaller than 90° in order that the racks may be transported as stacked on top of each other. Such a configuration of the rack permits the racks to be transported as stacked on top of each other. This leads to an efficient use of the space of the truck box. When bent racks are temporarily stored or the racks are temporarily stored at an installation site, a large number of racks may be stored in a limited space of the site so that an area occupied by the storage of the racks is reduced.

According to the invention, the weight of the weight member may be designed so as to be able to withstand a wind load on the solar cell unit.

According to the invention, a photovoltaic power generation system comprises: a plurality of solar cell units arranged along a direction of placement of racks of a solar cell module and/or along a direction perpendicular thereof, the solar cell unit including a rectangular- or square-shaped solar cell module including one or more solar cell elements; and the racks assembled to opposite sides of the solar cell module, respectively, the system further comprising a connecting member for interconnecting the racks of adjoining solar cell units.

By virtue of the connecting member for interconnecting the rack of one solar cell unit and the rack of the other solar cell unit, individual solar cell unit to be arranged may be readily positioned with respect to respective solar cell units of a longitudinal string. That is, the racks of a respective pair of adjoining solar cell units may be interconnected without performing a precise positioning. Even in a case where the installation surface includes an uneven portion, an inclined portion or joints, for example, the solar cell units may be connected with each other even though the solar cell units are not positioned on the installation surface with high precisions.

The positioning precisions as high as those of the prior art are not required and hence, the assembly steps are simplified and the fabrication costs and time are reduced, whereby the cost reduction is achieved.

In this manner, a required number of solar cell units can be installed simply by using the connecting member, so that the photovoltaic power generation system may employ a reduced number of components. Thus is provided a less costly photovoltaic power generation system.

According to the photovoltaic power generation system of the invention, a plural number of solar cell units are arranged along the direction of placement of the racks, so that the units as a whole are increased in weight. Thus, the solar cell modules and the like can be supported in a manner to ensure that the solar cell modules and the like are not blown away by the negative pressure load such as wind.

If the solar cell unit has a structure wherein the first rack has a greater height than the second rack thereby to incline the solar cell module, the solar cell module may be installed as inclined at a desired angle of, say, 1° to 15° or 30° to 45°. Thus, the efficiency of the photovoltaic power generation is increased.

The connecting member includes a connecting member for interconnecting the second rack of one of adjoining solar cell units and the first rack of the other solar cell unit, or a connecting member for interconnecting the respective first racks of adjoining solar cell units and/or the respective second racks thereof.

In a case of the connecting member for interconnecting the second rack of one of adjoining solar cell units and the first rack of the other solar cell unit, the second rack may be formed with a first fit portion at an end thereof whereas the first rack may be formed with a second fit portion an end thereof, and the connecting member may include a bent portion designed to clamp these fit portions in overlapped relation. This permits the solar cell module to be secured to the racks more rigidly than a case where the solar cell module is secured to the racks by means of screw and bolt. In addition, the drop-off of the solar cell module due to the rupture of the screw or bolt is eliminated so that the system is enhanced in safety.

Furthermore, the following problem is also eliminated. In a case where a photovoltaic power generation system including an array of a plural number of solar cell modules is installed and thereafter, a trouble occurs due to a lowered output of a certain solar cell module so that the solar cell module must be replaced, a structure wherein the plural solar cell units are interconnected by means of fastening bolts provides an extremely limited space for performing maintenance services such as to replace the solar cell module. In this structure, it is quite difficult to perform regular maintenance services such as the replacement of the component.

If a solar cell module located in the vicinity of the center of the system requires replacement, the conventional structure will make it almost impossible to remove the fastening bolt or to actually insert a tool in the bolt, because there is no maintenance space around this solar cell module.

According to the photovoltaic power generation system of the invention, on the other hand, the fastening member such as the screw and bolt is not used but only the connecting member is used for interconnecting the solar cell-units, as described above. Accordingly, the system is notably improved in constructability.

The first rack, the second rack and/or the connecting member may be formed from a conductive material such that the racks may be set at a substantially equal potential. Therefore, the racks may be easily connected with a common ground connector so that costs for the connection are reduced.

For ground connection, the first rack, the second rack and/or the connecting member may be formed from any one of conductive metals, conductive ceramics, conductive cermets and conductive synthetic resins. Alternatively, first rack, the second rack and/or the connecting member each may have a surface layer portion formed of a plate layer.

According to the invention, a structure may be made such that the weight member is placed on the first rack and/or the second rack, or a structure may be made such that the weight member is not placed on the rack. However, the weight members placed on the first rack and the second rack further enhance the effect that the solar cell modules and the like are supported in a manner to ensure that the solar cell modules and the like are not blown away by the negative pressure load such as wind.

In a case where the connecting member interconnects the respective first racks of adjoining solar cell units and/or the respective second racks thereof, the respective first racks of adjoining solar cell units or the respective second racks thereof may be interconnected and fixed to each other at a time. Thus, the plural solar cell units may readily be interconnected and installed, resulting in the improved constructability.

If the solar cell unit has a structure wherein the first rack has a greater height than the second rack thereby to incline the solar cell module, the solar cell module may be installed as inclined at a desired angle of, say, 1° to 15° or 30° to 45°. Thus, the efficiency of the photovoltaic power generation is increased.

If an arrangement is made such that each of the racks is formed with a connection guide portion and that the connecting member includes an upper member, a lower member and a fastening structure for fastening these members with each other, the upper member and the lower member may be fastened with each other in a state where the connection guide portion is inserted between the upper member and the lower member.

Particularly if an arrangement is made such that the connection guide portion is formed with a hole at a predetermined position, whereas the upper member is formed with a lug to be inserted in the hole formed in the connection guide portion, the back-forth and lateral movements of the solar cell unit are constrained by inserting the lug into the hole. Therefore, the solar cell units can be maintained in the interconnected state even if too great a strain for the interconnection merely by clamping and fastening to withstand is applied to the solar cell units.

The weight members placed on the first rack and the second rack are able to further enhance the effect that the solar cell modules and the like are supported in a manner to ensure that the solar cell modules and the like are not blown away by the negative pressure load such as wind.

According to the invention, a photovoltaic power generation system comprises: a rectangular- or square-shaped solar cell module including one or more solar cell elements; and racks assembled to opposite sides of the solar cell module, respectively, the system wherein a space region allowing an air flow therein is present under the solar- cell module, whereas an air-inflow blocking member for blocking the air flow into the space region is disposed in the vicinity of the space region.

According to this arrangement, the air-inflow blocking member is disposed in the vicinity of the space region under the solar cell module, thereby reducing or eliminating the air flow into the space region. Thus, a force of wind or the like to lift up the solar cell module may be decreased so that a shortage of weight is offset in the arrangement wherein the solar cell module is held at place by way of the combined weights of the first and second racks of the solar cell module. As a result, the solar cell modules and the like may be supported in a manner to ensure that the solar cell modules and the like are not blown away by the negative pressure load such as wind.

If an arrangement is made such that the air-inflow blocking member is provided with a slant plane for guiding an air flow toward the slant plane to flow over an upper side of the solar cell module, the air flow into the space region does not form cross wind against the system itself, thus flowing smoothly. Therefore, this arrangement provides an even greater effect in that the solar cell modules and the like may be supported in a manner to ensure that the solar cell modules and the like are not blown away by the negative pressure load such as wind.

The weight of the racks is defined to be a weight to withstand a wind load applied to the solar cell module, whereby further enhanced is the effect to support the solar cell modules and the like in a manner to ensure that the solar cell modules and the like are not blown away by the negative pressure load such as wind.

If the weight member is disposed at a predetermined place of the first rack and/or the second rack, the aforementioned effect may be enhanced even further.

### BRIEF DESCRIPTION OF THE DRAWINGS

FIG. 1 is a perspective view showing a solar cell unit;

FIG. 2 is a schematic sectional view showing a solar cell module of the solar cell unit;

FIG. 3 is an exploded perspective view showing the solar cell unit;

FIG. 4 is a perspective view showing a photovoltaic power generation system wherein plural solar cell units are arrayed;

FIG. 5 is a perspective view showing an upper side rack of the solar cell unit;

FIG. 6 is a perspective view showing a lower side rack of the solar cell unit;

FIG. 7 is a side view of the upper side rack;

FIG. 8 is a rear view of the upper side rack;

FIG. 9 is a perspective view showing the upper side racks in stacked relation for transportation;

FIG. 10 is a rear view showing a state where the solar cell module is assembled on the rack;

FIG. 11 is a rear view showing how to assemble the solar cell module on the rack;

FIG. 12 is a rear view showing how to assemble the solar cell module on the rack;

FIG. 13 is a perspective view showing two solar cell units assembled together;

FIG. 14 is a perspective view showing how the solar cell units are assembled together;

FIG. 15 is an enlarged perspective view showing how the upper side rack of one of the adjoining solar cell units is mounted with the lower side rack of the other solar cell unit;

FIG. 16 is an enlarged perspective view showing how the upper side rack of one of the adjoining solar cell units is connected with the lower side rack of the other solar cell unit by means of a connecting member;

FIG. 17 is a perspective view showing how the solar cell unit is assembled;

FIG. 18 is a perspective view showing how a weight member is placed on the solar cell unit;

FIG. 19 is a horizontal sectional view showing a method of connecting the racks;

FIG. 20 is a horizontal sectional view showing a state where the weight member is placed on the connected racks;

FIG. 21 is a perspective view of a photovoltaic power generation system including the plural solar cell units combined together;

FIG. 22 is a schematic horizontal sectional view showing how the racks of the solar cell units are connected with each other;

FIG. 23 a perspective view showing a state prior to the connection of the solar cell units;

FIG. 24 a perspective view showing the upper side rack and the lower side rack in fitting engagement;

FIG. 25 is a perspective view showing a state where the upper side rack and the lower side rack in fitting engagement are interconnected by means of a connecting fitting;

FIG. 26 is a perspective view showing a state where the upper side rack and the lower side rack are in fitting engagement by means of another structure;

FIG. 27 is a perspective view showing a state where the upper side rack and the lower side rack are in fitting engagement by means of still another structure;

FIG. 28 is a horizontal sectional view showing how the upper side rack and the lower side rack in fitting engagement are interconnected by means of the connecting fitting;

FIG. 29 is a perspective view showing four solar cell units transversely arranged;

FIG. 30 is a perspective view of a connecting member;

FIG. 31 is a perspective view showing a state prior to the insertion of the connecting member into connection guide portions of the racks;

FIG. 32 is a perspective view showing a state where two adjoining solar cell units are interconnected by means of the connecting member;

FIG. 33 is a perspective view showing a photovoltaic power generation system wherein the solar cell units are arranged in a matrix form;

FIG. 34 is a perspective view of a connecting member having another structure;

FIG. 35 is a perspective view of a connecting member having still another structure;

FIG. 36 is a perspective view of a connecting member having still another structure;

FIG. 37 is a perspective view showing a solar cell unit U provided with air-inflow blocking plates in the vicinity thereof;

FIG. 38 is a perspective view showing a photovoltaic power generation system including plural solar cell units arranged in a matrix form;

FIG. 39 is a perspective view showing the flow of wind blowing from a lateral side of the solar cell unit;

FIG. 40 is a perspective view showing the flow of wind blowing longitudinally of the solar cell unit;

FIG. 41 is a perspective view showing a photovoltaic power generation system provided with the air-inflow blocking plates in the vicinity thereof;

FIG. 42 is a perspective view showing the air-inflow blocking plate disposed on a lateral side of the solar cell unit;

FIG. 43 is a perspective view showing the air-inflow blocking plate disposed on a transverse side of the solar cell unit;

FIG. 44 is a perspective view showing an example of the air-inflow blocking plate provided with the weight member;

FIG. 45 is a perspective view showing a solar cell unit wherein an installation plane of the air-inflow blocking plate is extended to place under the solar cell unit;

FIG. 46 is a perspective view showing an example of the air-inflow blocking plate wherein a wind guide plate thereof is formed with a plurality of air holes;

FIG. 47 is a perspective view showing an example of the air-inflow blocking plate formed with slits; and

FIG. 48 is a perspective view showing a conventional photovoltaic power generation system.

### DETAILED DESCRIPTION OF THE INVENTION

A photovoltaic power generation system according to one embodiment of the invention will hereinbelow be described in details with reference to the accompanying schematic drawings.

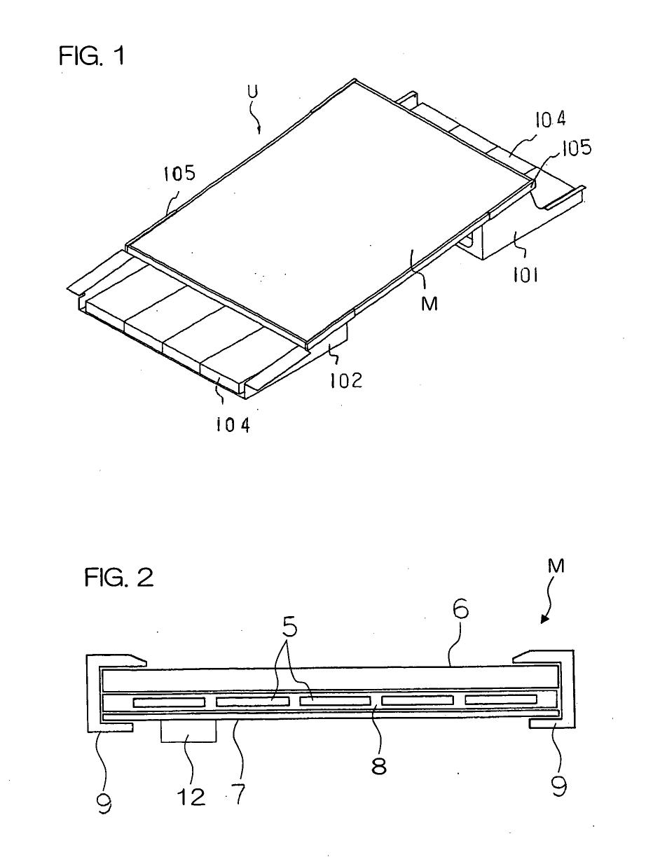

FIG. 1 is a perspective view showing a solar cell unit U.

The solar cell unit U comprises: a solar cell module M, an upper side rack 101 and a lower side rack 102, the upper and lower side racks serving to support the solar cell module M in an inclined position. The upper side rack 101 is equivalent to a “first rack”, whereas the lower side rack 102 is equivalent to a “second rack”.

The solar cell unit further employs a weight 104 for preventing the upper side rack 101 and the lower side rack 102 from being displaced from their installation places.

The weight 104 is, for example, a concrete block or a metal block such as of iron. FIG. 1 illustrates an example using four blocks on each side. However, one piece of the weight itself may be made heavier to reduce the division number to, say, two or conversely, one piece of the weight may be made lighter to increase the division number to, say, eight or sixteen, so long as the total weight is substantially the same. In this manner, the constructability may be improved.

Indicated at 105 in FIG. 1 is a mounting member (to be described hereinafter) for mounting the solar cell module M to the upper side rack 101 and the lower side rack 102. The mounting member 105 comprises a respective part of the upper side rack 101 and the lower side rack 102. The respective parts of the upper side rack and the lower side rack are so formed as to constitute the mounting member.

The upper side rack 101 and the lower side rack 102 may be formed by working a conductive metal sheet having high weather resistance, such as aluminum, SUS, copper and brass, into a predetermined shape, or by molding ceramics, synthetic resin or the like into a predetermined shape.

The solar cell unit U is installed on an installation surface such as a flat roof.

FIG. 2 is a schematic sectional view of the solar cell module M.

The solar cell module M comprises a plurality of solar cell elements 5 electrically interconnected in series and/or in parallel and covered with a material having weather resistance.

The solar cell element 5 comprises a crystalline solar cell such as of monocrystalline or polycrystalline silicon, or a thin-film solar cell.

The solar cell elements 5 are covered by a filler 8 comprising a transparent synthetic resin such as EVA (ethylene-vinyl acetate copolymer).

The solar cell element 5 is provided with an optically transparent plate 6, such as a glass plate or a synthetic resin plate, on a photoreceptive surface thereof. The solar cell element has its non-photoreceptive surface covered with a weather resistant film 7 such as a Teflon (R) film, PVF (polyvinyl fluoride) film or PET (polyethylene terephthalate) film.

A junction box 12 such as formed from a synthetic resin such as ABS or from aluminum may be bonded onto the weather resistant film 7. An output power of the solar cell module M is drawn out by means of the junction box 12.

A laminate of the optically transparent plate 6, the solar cell elements 5 and the weather resistant film 7 constitutes a rectangular solar cell module M.

A frame 9, such as of aluminum or SUS, is clampingly assembled onto a periphery of each of the sides of the solar cell module M thereby strengthening the whole body of the solar cell module M.

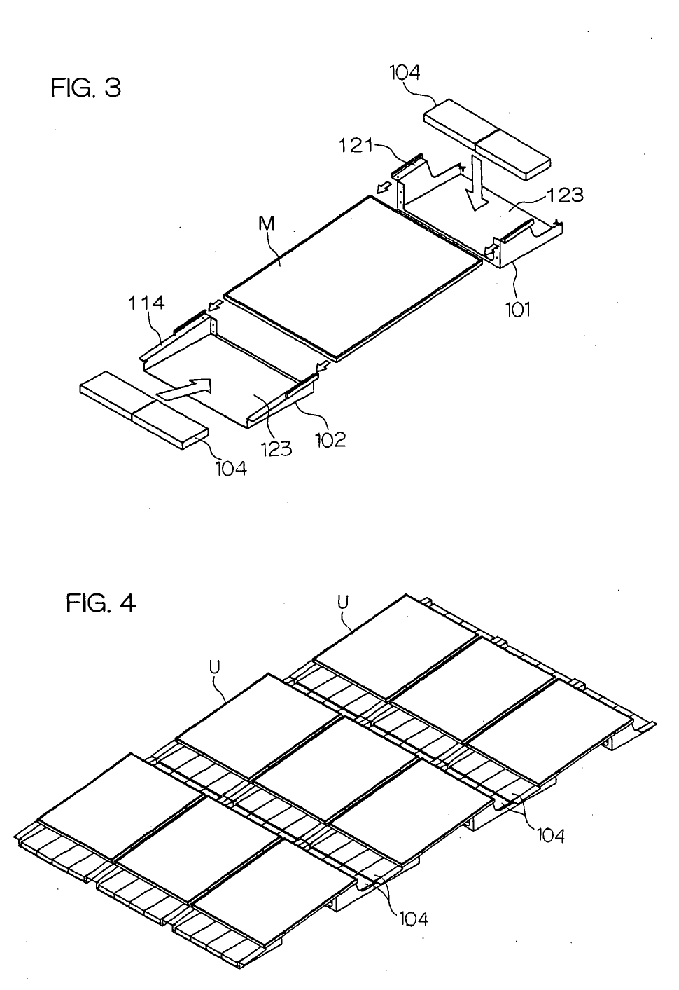

FIG. 3 is an exploded perspective view of the solar cell unit U. FIG. 4 is a perspective view showing a plurality of solar cell units U arranged in plural arrays. FIG. 4 illustrates a case where nine solar cell units U are employed.

As shown in FIG. 3, the solar cell module M with the frame 9 is placed on a receiver 121 of the upper side rack 101 and a receiver 114 of the lower side rack 102.

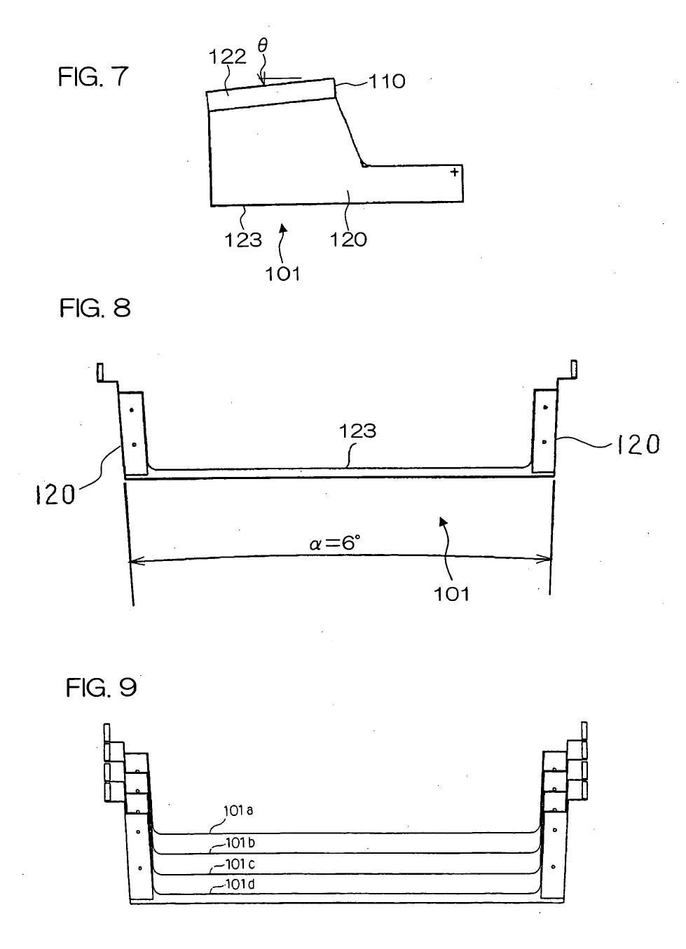

These upper side rack 101 and lower side rack 102 are constructed to have different heights, so that the solar cell module M is installed in an inclined position. This inclination is represented by “θ” (see FIG. 7).

The receiver 121 of the upper side rack 101 has the inclination θ relative to a bottom surface of the upper side rack 101, whereas the receiver 114 of the lower side rack 102 also has the inclination θ relative to a bottom surface of the lower side rack.

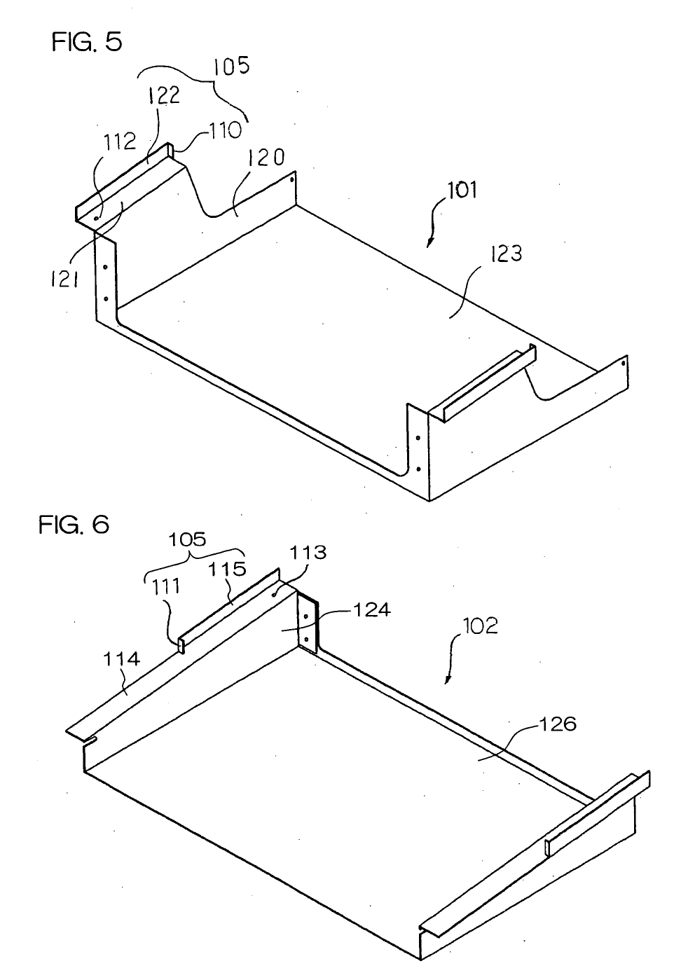

FIG. 5 is a perspective view showing the upper side rack 101. FIG. 6 is a perspective view showing the lower side rack 102. FIG. 7 is a side view of the upper side rack 101.

The upper side rack 101 is formed with bent pieces 120 which are formed by folding up opposite ends of a bottom 123 thereof, which is comprised of the sheet formed from the aforementioned material. An upper end of the bent piece 120 is folded outwardly. This outwardly folded portion is the receiver 121. A distal end of the receiver 121 is further folded up substantially vertically. This vertically folded portion is a guide 122. The guide 122 functions to guide the solar cell module M in insertion. A bent portion 110 at one end of the guide 122 is folded inwardly in order to prevent the solar cell module M from moving back and forth. A combination of the guide 122 and the bent portion 110 is referred to as the “mounting member 105”.

The receiver 121 is further formed with a hole 112, via which the solar cell module M is fastened with a screw.

The lower side rack 102 is formed with bent pieces 124 which are formed by folding up opposite ends of a bottom 126 thereof, which is comprised of the sheet formed from the aforementioned material. An upper end of the bent piece 124 is folded outwardly. This outwardly folded portion is the receiver 114. A distal end of the receiver 114 is further folded up substantially vertically. This vertically folded portion is a guide 115. The guide 115 functions to guide the solar cell module M in insertion. One end of the guide 115 is folded inwardly so as to prevent the solar cell module M from moving back and forth. This folded portion is a bent portion 111. A combination of the guide 115 and the bent portion 111 is referred to as the “mounting member 105”

The receiver 114 is further formed with a hole 113, via which the solar cell module M is fastened with a screw.

The solar cell module M may be secured to the upper side rack 101 and the lower side rack 102 as follows. The respective mounting members 105 of the upper side rack 101 and the lower side rack 102 are slid on the frame 9 of the solar cell module M along a longitudinal direction thereof until the frame 9 is contacted by the respective bent portions 110, 111 of the upper side rack 101 and the lower side rack 102. Subsequently, bolts are inserted through individual holes (not shown) formed in the frame 9 of the solar cell module M, and through the individually corresponding holes 112 and 113 in the upper side rack 101 and the lower side rack 102. The bolts are fastened with nuts whereby the solar cell module is secured to the racks. Alternatively, thread may be formed in either one of the corresponding holes and then, a bolt may be screwed into the holes to secure the solar cell module.

Subsequently, the weights 104 are placed on each of the upper side rack 101 and the lower side rack 102. Thus, the solar cell unit U is fixed to the installation place.

The weights 104 are provided for preventing the solar cell unit U from being blown away by wind pressure or the like, or from being turned upside down. The details of the weights will be described hereinafter with reference to FIG. 18.

According to such a structure, the solar cell unit U may be assembled using a tool as simple as a screw driver. This construction method is simpler than the conventional construction method. Furthermore, the construction method features a simple and easy assembly procedure wherein the system is assembled by repeating the simple work. As compared with the conventional work mode wherein one step requires a plural number of works, the construction method of the invention reduces the number of workers and the incidence of assembly defects due to human errors.

A plural number of solar cell units U thus assembled may be installed on the flat roof or the like, as shown in FIG. 4, whereby a photovoltaic power generation system providing a desired power output is constructed.

According to the structure of the solar cell unit U of the embodiment, the solar cell unit U may be fixed to the installation place by way of the dead weight thereof. This negates the need for the foundation works including the burial of anchors in the roof and the like, so that the period of construction may be shortened.

This also permits the solar cell unit U to be suitably installed in a direction to receive a large quantity of solar radiation or to generate a large quantity of power.

In a case where the installation surface is replaced because it is aged due to the solar radiation on the flat roof, the whole body or a part of the photovoltaic power generation system may be readily disassembled and transferred. This also provides for maintenance work of the installation surface, which is impracticable in the conventional system wherein the foundation is embedded.

Those parts of the system other than the solar cell module have weights (7 kg or so) small enough for one worker to carry, so that potential danger involved in the transportation of heavy articles may be reduced notably.

The embodiment has the structure wherein the upper side rack 101 and the lower side rack 102 are mounted to the solar cell module M at the opposite sides thereof. On a back side of the solar cell module M, therefore, there is produced a region where the upper side rack 101 and the lower side rack 102 are out of contact with the module. Thus is defined a ventilation space. Air flow through such a space cools the solar cell module M so that the efficiency of the power generation is increased.

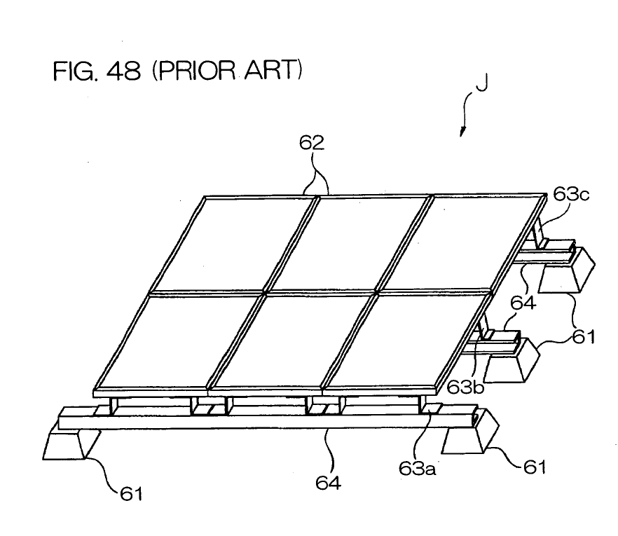

Just for reference, each solar cell unit U according to the conventional construction method shown in FIG. 48 requires eight parts. In contrast, each solar cell unit U of the photovoltaic power generation system of the invention is constituted by three components including the upper side rack 101, the lower side rack 102 and the weight 104. Thus, the invention is superior to the conventional art in the constructability, the reduction of the number of components, and the transportability.

Next, description is made on a mode of transporting metal components such as the upper side rack 101 and the lower side rack 102.

FIG. 8 is a rear view of the upper side rack 101. FIG. 9 is a rear view of a stack of plural upper side racks 101 to be transported.

The bent pieces 120 of the upper side rack 101 are formed by bending. The bent piece 120 is bent at an angle slightly smaller than 90°. It is assumed that an angle provided by the opposite bent pieces 120 is defined as α. The angle α is selected from the range of 1 to 15°.

FIG. 8 illustrates a case where the bent pieces 120 of the upper side rack 101 are bent at an angle of 3°, respectively (α=6°).

By inclining the bent pieces 120 of the upper side rack 101 in this manner, the upper side racks 101 (101a to 101d) can be transported in stacked relation as shown in FIG. 9. This provides for not only an efficient use of space in a truck box or the like, but also an efficient use of limited space when the upper side racks 101 are temporarily stored at a construction site.

The lower side rack 102 may also be subjected to the same bending process as the above, thereby providing the same working effect.

The upper side rack may also be constructed such that an upper part of the guide 122 of the bent piece 120 is folded back so as to fix the solar cell module M.

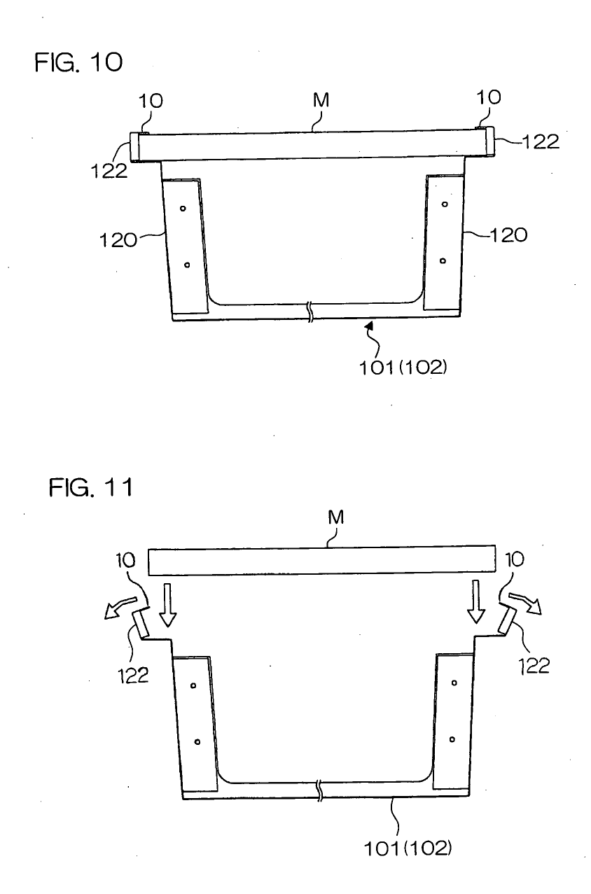

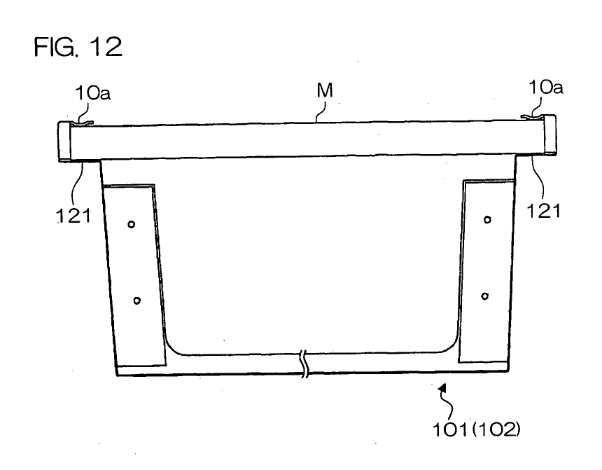

FIG. 10 is a rear view showing the structure wherein the upper part of the guide 122 of the bent piece 120 is further folded inwardly. FIG. 11 and FIG. 12 are rear views showing how to assemble the solar cell portion on the rack. While the figures illustrate the upper side rack 101, the lower side rack 102 may also be constructed such that an upper part of the guide 115 of the bent piece 124 is further folded back. The illustration of the lower side rack 102 is not particularly made.

The portion formed by folding the upper part of the guide 122 inwardly is defined as a fold-back portion 10. In a case where the upper side rack 101 and the lower side rack 102 are fitted on the solar cell module M by sliding the racks over the frame 9 of the solar cell module M, the fold-back portions 10 can hold down the solar cell module M against a force caused by negative pressure load such as wind and acting to lift up the solar cell module M.

This effect is combined with the force of fixing the solar cell module M to the receivers 121, 114 of the upper side rack 101 and the lower side rack 102 via the screws and bolts, so as to achieve rigid fixing of the solar cell module M, which is prevented from dropping off and thence is enhanced in safety.

Without using the screws and bolts, the fold-back portions 10 alone are capable of fixing the solar cell module M.

If the structure adopting the aforesaid fold-back portion 10 is made such that the elasticity of the rack structure itself allows the guide 122 to expand outwardly, as shown in FIG. 11, the installation or removal of the solar cell module M may be carried out without transferring the upper side rack 101 and the lower side rack 102. This results in an improved performance against the negative pressure load, while in the meantime, the constructability is not lowered.

If lateral sides or such of the frame 9 of the solar cell module M are secured to the guides 122 by means of screws or fasteners thereby preventing the guides 122 from being freely expanded, the solar cell module M becomes more resistant against force pulling away the solar cell module M, so that the safety of the system is further enhanced.

Alternatively, the fold-back portion 10 per se may be so constructed as to have elasticity.

FIG. 12 is a rear view showing the upper side rack 101 including a fold-back portion 10a having the elasticity. While the figure illustrates the upper side rack 101, the lower side rack 102 may also be constructed such that the fold-back portion has the elasticity.

A fold-back portion 10a provides the following merit. If the fold-back portions 10a clamp the solar cell module M as pressing down the solar cell module M against the receivers 121, 114 of the upper side rack 101 and the lower side rack 104, the solar cell module M may be fixed to the upper side rack 101 and the lower side rack 104 without using the screws and bolts. As a result, the work performance is increased.

Next, a photovoltaic power generation system according to another embodiment of the invention is described.

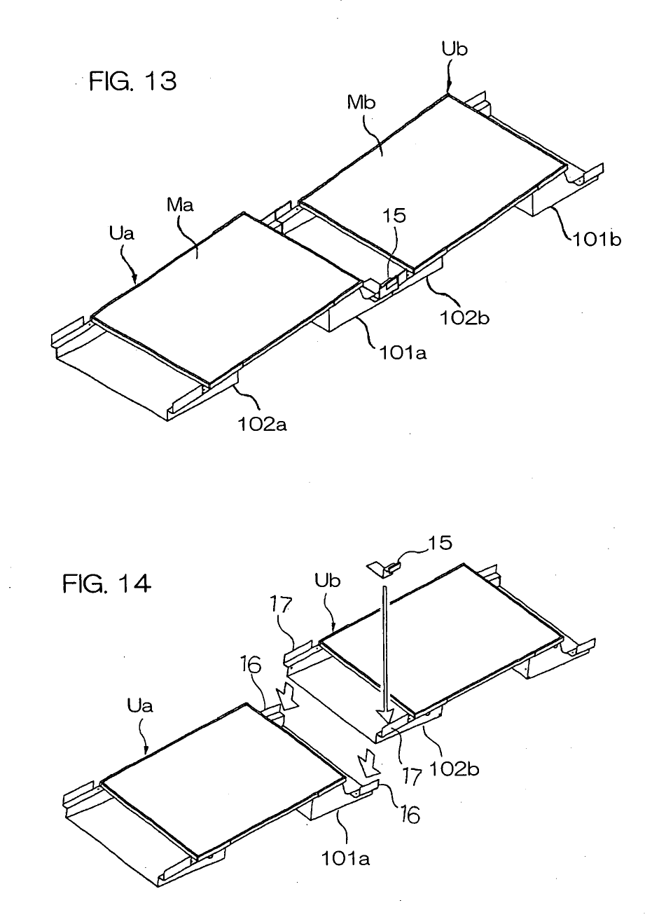

FIG. 13 is a perspective view showing two solar cell units Ua, Ub (collectively referred to as “solar cell units U”) assembled together, whereas FIG. 14 is a perspective view showing how the solar cell units are assembled together.

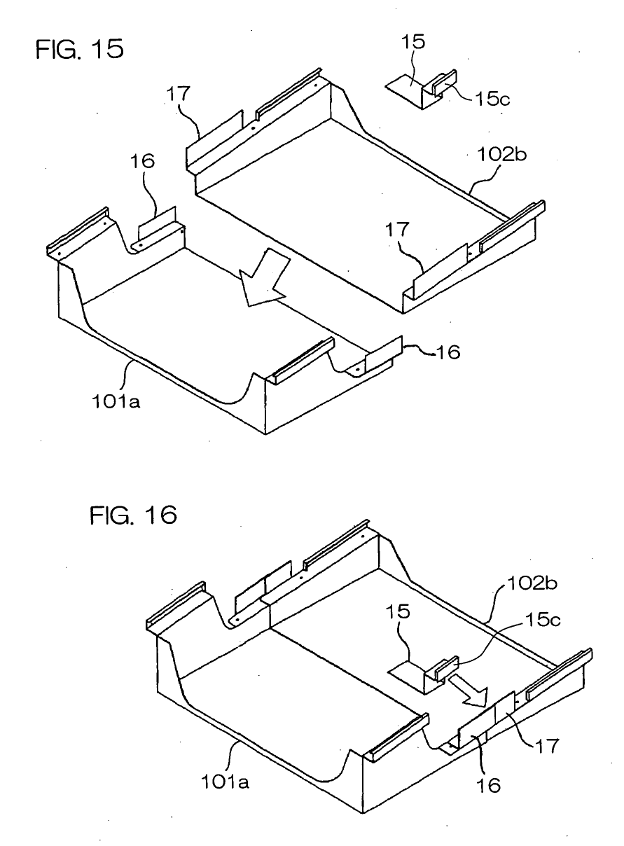

FIG. 15 and FIG. 16 are enlarged perspective views each showing how the rack of one of the adjoining solar cell units U is connected with the rack of the other solar cell unit by means of a connecting member.

As shown in FIG. 13, the connection of the solar cell units Ua, Ub is accomplished by fixing fit portions of the solar cell unit Ua and the solar cell unit Ub to each other by means of a connecting fitting 15 as the connecting member.

The solar cell unit U comprises the solar cell module M unitized with the racks by assembling the solar cell module M with the lower side rack 102 and the upper side rack 101.

These racks 101, 102 are each formed from a conductive metal such as aluminum, SUS, copper and brass. Each of the racks is obtained by working the above material into a predetermined shape. Alternatively, the racks may also be formed from any of the materials including conductive ceramics, conductive cermet and conductive synthetic resins.

Furthermore, each of the racks 101, 102 may also have a structures wherein a surface layer portion thereof contacting the connecting fittings 15 is formed of a plate layer. The plate layer may be formed by electrolytic plating or electroless plating.

On the other hand, the connecting fitting 15 may also be formed from a conductive metal such as aluminum SUS, copper and brass, and be worked into a predetermined shape. Any of the materials including conductive ceramics, conductive cermet and conductive synthetic resins is also usable.

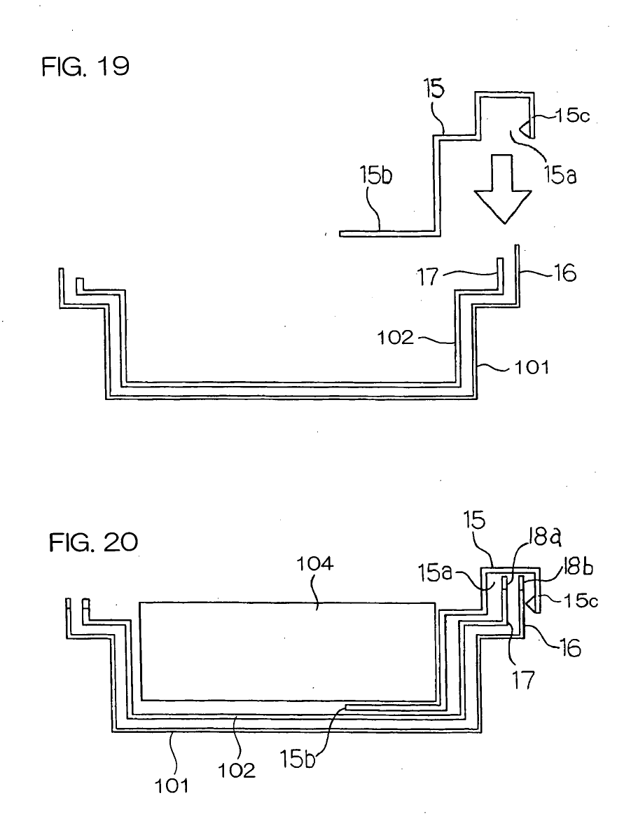

The connecting fitting 15 is formed by folding an elongate piece of metal sheet in two steps, as shown in FIG. 15, followed by folding back a distal end 15c of the metal sheet substantially at 1800 so as to clamp the plate-like bodies of the upper side rack 101 and the lower side rack 102. The details of the connecting fitting will be described hereinafter with reference to FIG. 19 to FIG. 22.

Next, an assembly procedure is described with reference to FIG. 14. A lower side rack 102b of the solar cell unit Ub is partially or bodily inserted in an upper side rack 101a of the solar cell unit Ua.

The upper side rack 101 is formed with a first fit portion 16 at an end thereof. When a second fit portion 17 formed at an end of the lower side rack 102 is inserted in the first fit portion 16, both the fit portions 16, 17 are arranged in parallel.

The connecting fitting 15 is fitted on these portions from above, whereby the first fit portion 16 and the second fit portion 17 are fixed to each other by means of the connecting fitting 15.

Such a fixing process is specifically shown in FIG. 15 and FIG. 16.

According to the photovoltaic power generation system of the embodiment, a plural number of solar cell units U are prepared, which are connected and fixed to each other by fitting the connecting member (connecting fitting 15) on the fit portions formed at the respective ends of the lower side rack and the upper side rack of adjoining solar cell units U. The solar cell units U may be aligned with each other by such a simple operation and hence, the assembly procedure is simplified.

Furthermore, the embodiment is arranged such that one of the fit portions (16, 17) is inserted in the other fit portion whereby the solar cell units U are aligned with each other. This facilitates the positioning of the solar cell units U.

The embodiment has the structure wherein the first fit portion 16 and the second fit portion 17 are fixed to each other by means of the connecting fittings 15. Thus, the embodiment achieves a more rigid connection of the solar cell units than the arrangement wherein the solar cell module is fixed to the racks by means of the screws and bolts. In addition, the drop-off of the solar cell module due to the rupture of the screw or bolt is eliminated so that the system is enhanced in safety.

Next, a photovoltaic power generation system according to another embodiment of the invention is described.

According to the photovoltaic power generation system of the embodiment, the photovoltaic power generation system described in the foregoing is further provided with a weight member.

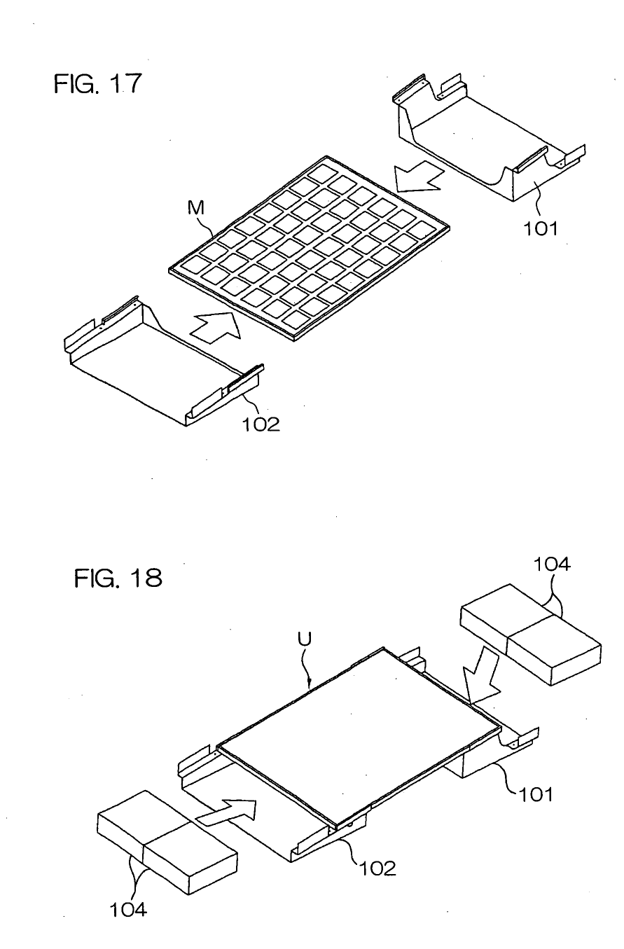

FIG. 17 is a perspective view showing how the solar cell unit U is assembled.

As shown in FIG. 2, the solar cell module M is a heavy article including the glass, the solar cell elements, the filler and the like. The lower side rack 102 and the upper side rack 101 are articles formed by folding a metal sheet such as of iron, aluminum or stainless steel, or molded articles. Thus, the total weight of the lower and upper side racks is in the range of about a dozen kilograms to tens of kilograms.

However, if the lower side rack 102 and the upper side rack 101 are not fixed to the installation surface by anchoring or the like, the racks are decreased in the resistance against the wind load even though the racks have the aforementioned weight.

As shown in FIG. 18, therefore, the weights 104, as the weight member formed of concrete blocks or metal such as iron, are disposed in the lower side rack 102 and the upper side rack 101.

Thus, the solar cell unit U is rigidly pressed against the installation surface by the heavy articles, so as to be imparted with the resistance against the wind load.

The embodiment is constructed such that the rack on one side and the rack on the other side are provided with counterweights (the weight member). Accordingly, the assembly procedure for the solar cell unit U is simplified. As a result, the work efficiency is increased so that the fabrication cost is reduced.

In addition, the installation surface such as the roof does not require the foundation works including anchoring and the like. This also leads to the prevention of defects such as invasion of rain water, which may result from the foundation works. Furthermore, works for waterproofing the installation surface may be omitted.

The following procedure may be taken to install the solar cell units U, for example. A procedure includes the steps of: arranging the solar cell units U on the flat roof, and then placing the weight members in each of the racks. An alternative procedure includes the steps of: mounting the weight members on each of the racks, installing the individual racks with the weight members on the flat roof, and assembling the solar cell modules M on the racks.

As described above, the working procedure is not limited, so that a suitable installation procedure may be selected in the light of the work performance.

The weight of the weight member may be designed based on a standard that the weight member is able to withstand the wind load against the solar cell units U.

It is noted that the lower side rack 102 and the upper side rack 101 are not necessarily provided with the weights 104 having the same weight or the same configuration. Weights discretely having different weights or different configurations may be applied to the lower side rack 102 and the upper side rack 101.

Next, a photovoltaic power generation system according to still another embodiment of the invention is described.

FIG. 19 and FIG. 20 are schematic sectional views each showing a structure interconnecting the lower side rack 102 and the upper side rack 101. FIG. 19 shows a state prior to the connection, whereas FIG. 20 shows a post-connection state where the weight 104 is placed on the racks.

First, as shown in FIG. 19, the connecting fitting 15 includes a fitting groove 15a for bringing the second fit portion 17 of the lower side rack 102 and the first fit portion 16 of the upper side rack 101 into fitting engagement. The connecting fitting 15 further includes a seat portion 15b designed to be in tight contact with the bottom surface of the lower side rack 102.

The first fit portion 16 and the second fit portion 17 are brought into the fitting engagement by means of the fitting groove 15a of the connecting fitting 15, whereby the solar cell unit Ua and the solar cell unit Ub are connected and fixed to each other, as shown in FIG. 13.

Furthermore, as shown in FIG. 20, the seat portion 15b of the connecting fitting 15 extends along the bottom of the lower side rack 102 in tight contact therewith, so that the weight 104 can press down the connecting fitting 15, the lower side rack 102 and the upper side rack 101 against the installation place. Thus, the connecting fitting 15 is also rigidly fixed to place, so that the lower side rack 102 and the upper side rack 101 are also rigidly connected and fixed to each other.

While the embodiment is described on assumption that the lower side rack 102 is inserted in the upper side rack 101, the same working effects may be obtained if the upper side rack 101 is inserted in the lower side rack 102.

As shown in FIG. 20, the first fit portion 16 of the upper side rack 101 may also be formed with a conductive portion 18a at place where the first fit portion is connected by the connecting fitting 15, whereas the second fit portion 17 of the lower side rack 102 may also be formed with a conductive portion 18b at place where the second fit portion is connected by the connecting fitting 15.

If an arrangement is made such that the conductive portion 18a and the conductive portion 18b are brought into contact with each other by the connecting fitting 15 when the solar cell unit Ua and the solar cell unit Ub are interconnected, the lower side rack 102 and the upper side rack 101 are electrically connected with each other. Thus is accomplished the connection with a casing ground in parallel with the fixing of the photovoltaic power generation system. Hence, there is obtained an effect to negate the need for connecting each solar cell unit U wit a ground connector, resulting the reduction of cost for ground connection.

The conductive portion and/or the connecting member may be formed from any of conductive metals, conductive ceramics, conductive cermet and conductive synthetic resins. In an alternative structure, the surface layer portion of the rack and/or the connecting member may be formed of a plate layer.

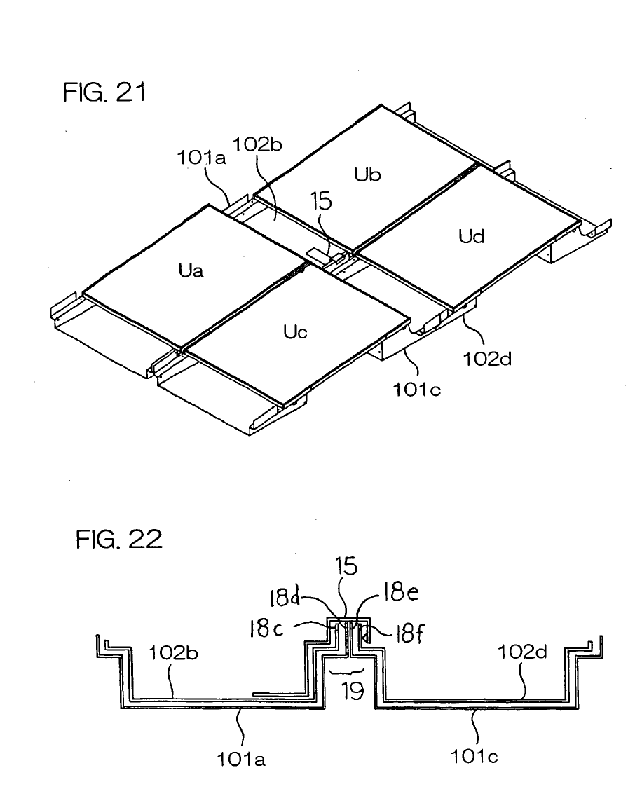

Next, referring to FIG. 21 and FIG. 22, description is made on how a plural number of solar cell units U are interconnected longitudinally and transversely by means of the connecting fittings 15.

FIG. 21 is a perspective view of the photovoltaic power generation system, whereas FIG. 22 is a schematic horizontal sectional view showing how the racks of the solar cell units U are transversely connected with each other.

In a system including a plural number of solar cell units U (Ua to Ud) as shown in FIG. 21, the lower side rack 102b of the solar cell unit Ub is inserted in the upper side rack 101a of the solar cell unit Ua, while the lower side rack 102d of the solar cell unit Ud is inserted in the upper side rack 101c of the solar cell unit 10c the same way.

Then, the solar cell units Ua and Ub are transversely adjoined by the solar cell units Uc and Ud.

As shown in FIG. 22, the connecting fitting 15 is fitted on a point of meeting 19 where the lower side racks and upper side racks of the solar cell units Ua to Ud meet. Thus, the four solar cell unit Ua to Ud are interconnected.

Subsequently, the weights are placed on each of the solar cell units Ua to Ud, as described above.

The individual solar cell units U are rigidly interconnected by means of the connecting fitting 15. If the solar cell unit Ua, for example, is subjected to the wind load in a focused way so as to be lifted up, the solar unit is held down by the weight of the other solar cell units Ub to Uc. Hence, the solar cell units combined together are capable of withstanding a greater wind load, as compared with a case where the solar cell unit is singly installed.

Next, description is made on another example of the connecting structure used for interconnecting the individual solar cell units U.

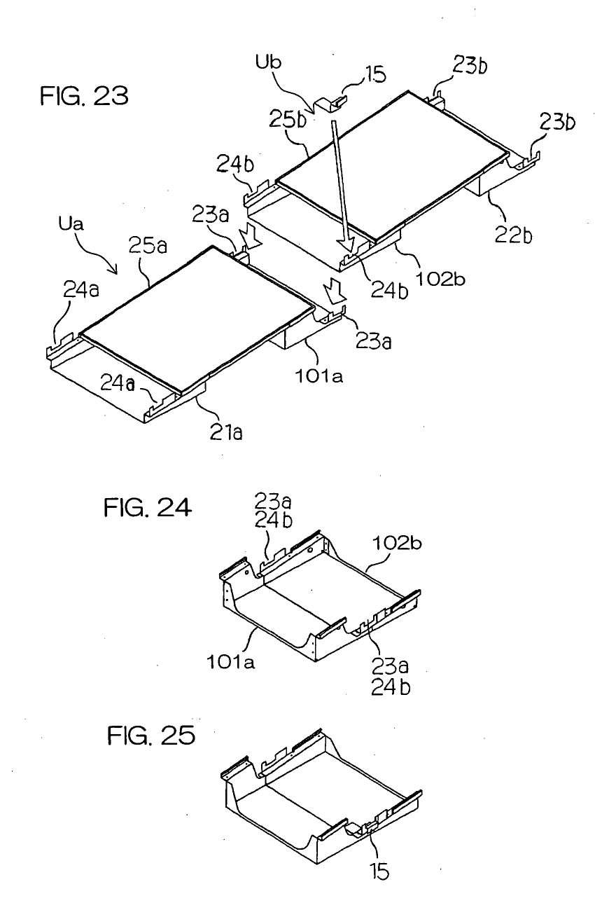

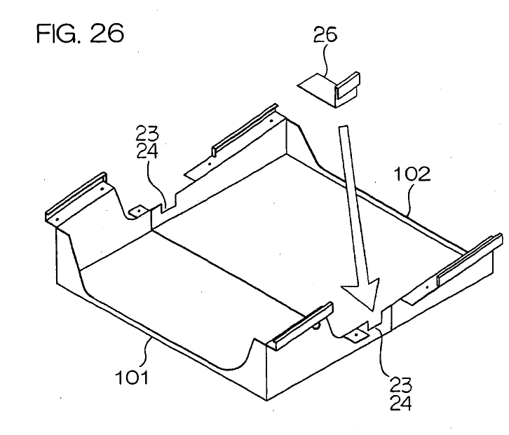

FIG. 23 is a perspective view showing a state prior to the interconnection of the solar cell units U. FIG. 24 is a perspective view showing the upper side rack and the lower side rack in fitting engagement. FIG. 25 is a perspective view showing a state where the upper side rack and the lower side rack in fitting engagement are interconnected by means of the connecting fitting 15.

As shown in FIG. 23, the lower side rack 102 of the solar cell unit U is formed with a second guide groove 24, whereas the upper side rack 101 is formed with a first guide groove 23. The second guide groove 24 and the first guide groove 23 are each formed with a rectangular notch. This permits the lower side rack 102 and the upper side rack 101 interconnected by the connecting fitting 15 to be fixed to each other at place closer to the bottom surface. Hence, the height of the connecting fitting 15 may be reduced.

Then, the lower side rack 102b of the solar cell unit Ub is inserted in the upper side rack 101a of the solar cell unit Ua. At this time, as shown in FIG. 24, the solar cell units are positioned in a manner to align the first guide groove 23a of the upper side rack 101a of the solar cell unit Ua with the second guide groove 24b of the lower side rack 102b of the solar cell unit Ub. Thus, the front and back solar cell units U can be aligned.

As shown in FIG. 25, the first guide groove 23 and the second guide groove 24 are fixed to each other at their notches by means of the connecting fitting 15. Accordingly, the solar cell units Ua, Ub are rigidly interconnected so that the solar cell units Ua, Ub are less likely to displace forwardly or rearwardly.

The same effects may also be obtained by applying the technique illustrated by the embodiment to the four solar cell units U as shown in FIG. 21, thereby collectively interconnecting these units.

FIG. 26 is a perspective view showing a state where the upper side rack and the lower side rack are brought in fitting engagement by means of still another connecting structure.

As shown in FIG. 26, the first guide groove 23 and the second guide groove 24 formed at the lower side rack 102 and the upper side rack 101 are located more loser to the bottom surface.

Accordingly, a fixing bracket 26 having a bent shape for reinforcing the lower side rack 102 or the upper side rack 101 may be reduced in the number of folds or may be reduced in the length thereof. This provides an advantage that the structures of the fixing bracket 26, the lower side rack 102 and the upper side rack 101 are simplified.

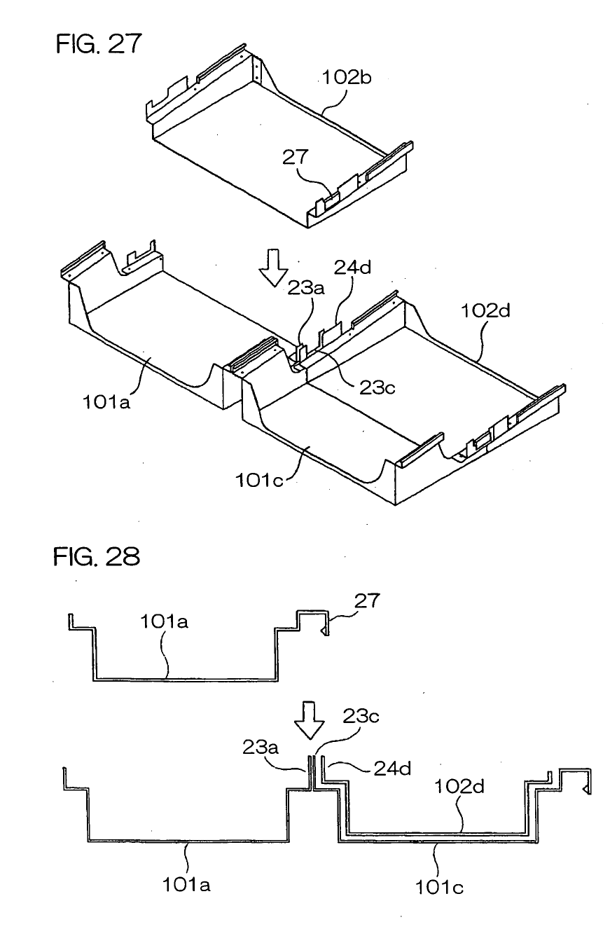

Still another connecting structure is shown in FIG. 27.

FIG. 27 shows a structure unitizing the connecting fitting and the lower side rack or the upper side rack.

As shown in FIG. 27, the lower side rack 102b is formed with a connecting portion 27 at place where the guide groove should be present. This connecting portion 27 is fitted on the guide grooves (23a, 23c, 24d) of the upper side racks 101a, 101c and the lower side rack 102d which are previously arranged.

The connecting portion 27 may be formed by folding a part of the lower side rack or the upper side rack. Otherwise, the connecting portion may be constructed by fixing a connecting fitting with a screw or a rivet.

Such a structure permits the upper side rack 101a, the upper side rack 101c, the lower side rack 102b and the lower side rack 102d to be interconnected at a time when the lower side rack 102b is mounted, as shown in FIG. 28. This results in the reduction of the number of components as well as the elimination of the step of fitting the connecting fitting.

While the embodiment illustrates the connecting portion 27 formed at the lower side rack, the same working effects may also be obtained by forming the connecting portion at the upper side rack.

Since the connecting portion and the rack are unitized, as described above, the three effects including the interconnection, the ground connection and the like are obtained at a time when the solar cell units are mounted. This results in the reduction of the steps of installation works.

As specifically described by way of the embodiments hereof, the photovoltaic power generation system of the invention reduces the number of components of the rack and negates the need for the conventional installation works including the steps of positioning and interconnecting the units with the screws, thereby achieving the shortened period of installation works.

Furthermore, such an arrangement does not require a member for previously fixing the connecting member. Therefore, when a particular one of the solar cell modules is dismounted for maintenance service or the like after installation, the solar cell module may be readily dismounted by removing the connecting member.

A photovoltaic power generation system according to still another embodiment of the invention will be described as below.

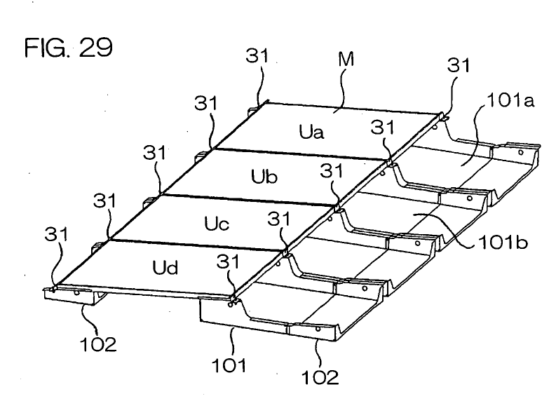

FIG. 29 shows a photovoltaic power generation system wherein four solar cell modules are assembled and connected with each other. In this photovoltaic power generation system, the solar cell modules are arranged along a direction perpendicular to a direction of the placement of the pair of racks.

As shown in FIG. 29, the photovoltaic power generation system includes four solar cell units U (Ua, Ub, Uc, Ud) arranged in a string, each solar cell unit including the upper side rack 101 and the lower side rack 102.

The solar cell module M of each of the solar cell units has a square or rectangular shape. In each of the solar cell units U, disposed at the opposite sides thereof are the lower side rack 102 for bearing one end of the solar cell module M at a lower height, and the upper side rack 101 for bearing the other end of the solar cell module M at a greater height. Thus, the solar cell module M may be supported in an inclined position.

When the plural solar cell units U are arranged in adjoining relation, the adjoining upper side racks 101 and solar cell modules M are connected and fixed to each other by means of a connecting/fixing fitting 31, whereas the adjoining lower side racks 102 and solar cell modules M are connected and fixed to each other by means of the connecting/fixing fitting 31.

The connecting/fixing fittings. 31 is formed by working a conductive metal sheet, such as of aluminum, SUS, copper and brass, into a predetermined shape.

While the embodiment arranges the four solar cell units U along the direction perpendicular to the direction of the placement of the pair of racks, additional solar cell units U may also be arranged in the direction of the placement of the pair of racks. Thus, the solar cell units U may be arranged in a matrix form.

Such a matrix arrangement may be accomplished by partially overlapping the respective lower side racks 102 of solar cell units U to be installed in the next step on the respective upper side racks 101.

Because of such a matrix arrangement of the solar cell units U, the solar cell units Ua to Ud are also pressed down by the weight of the solar cell units U installed in the next step, whereby the system is increased in the resistance against the uplift due to the wind load or the like.

Next, description is made on how the two adjoining solar cell units Ua, Ub are fixed to each other as clamped by means of the connecting/fixing fitting 31.

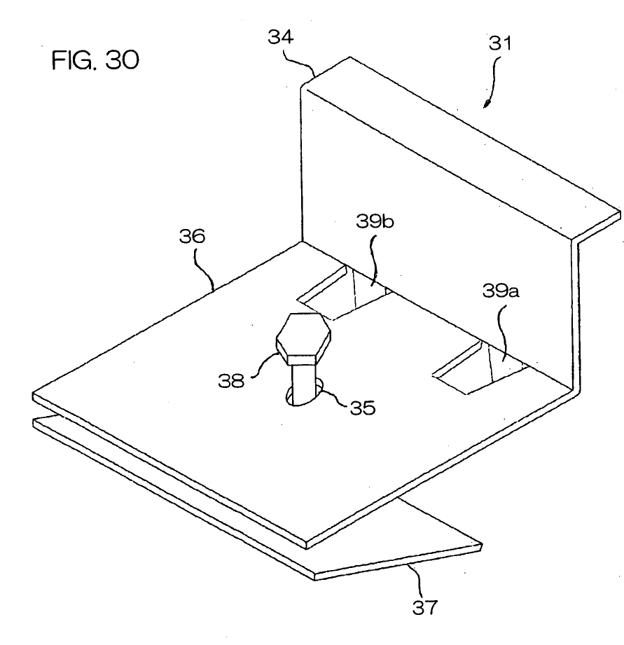

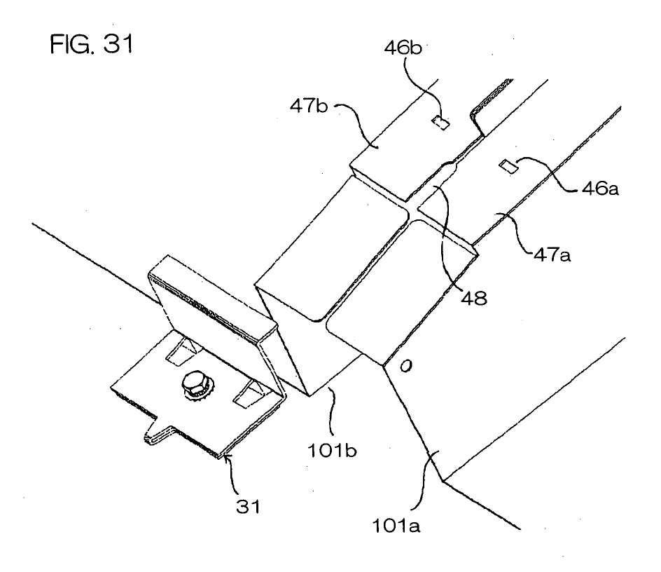

FIG. 30 is a perspective view of the connecting/fixing fitting 31.

The connecting/fixing fitting 31 comprises an upper member 36, a lower member 37 and a bolt 38 as a fastening member. A screw may be used in place of the bolt 38.

The upper member 36 is formed with two or more lugs 39a, 39b (collectively referred to as “lug 39”) which are projected toward the lower member 37.

One side of the upper member 36 is bent so as to define a solar-cell pressing portion 34 for preventing the uplift of the solar cell unit U.

The upper member 36 is further formed with a through-hole 35 for the bolt 38 to penetrate therethrough. The bolt 38 is designed such that after penetrating through the through-hole 35, the bolt cooperates with a screw hole formed in the lower member 37 and a nut soldered to the lower member or a separate nut so as to clamp and fix a connection guide portion 47 (to be described hereinafter) interposed between the upper member 36 and the lower member 37.

As described above, the connecting/fixing fitting is fastened by means of the bolt 38, the through-hole 35, the lower member 37 and the screw hole formed therein.

Next, description is made on a part of the frame of the solar cell unit U, which is clamped by the connecting/fixing fitting 31.

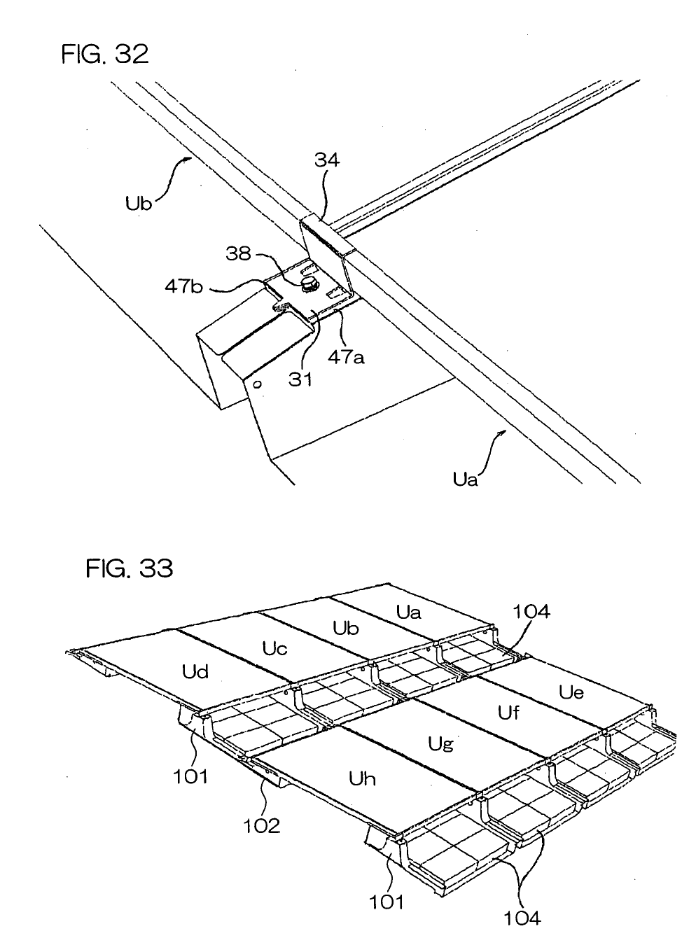

FIG. 31 is a perspective view showing a state prior to the insertion of the connecting/fixing fitting 31 into the connection guide portions of the upper side racks 101a, 101b. FIG. 32 is a perspective view showing a state where the connecting/fixing fitting 31 is inserted in the connection guide portions of the upper side racks 101a, 101b thereby interconnecting the adjoining solar cell units U.

Similarly to the connection guide portions of the upper side racks 101, connection guide portions of the lower side racks 102 are also interconnected by means of the connecting/fixing fitting 31.

Since the connection guide portion of the lower side rack 102 has the same structure as that of the upper side rack 101, the following description is made on the connection guide portion of the upper side rack 101 while the description on the connection guide portion of the lower side rack 102 is dispensed with.

As shown in FIG. 31, the upper side racks 101, 101b of the solar cell units Ua, Ub are formed with connection guide portions 47a, 47b (collectively referred to as “connection guide portion 47”) bent outwardly of the individual racks. These connection guide portions 47a, 47b are respectively formed with holes 46a, 46b (collectively referred to as “hole 46”). The connection guide portion 47 has a slightly smaller width at an end thereof than that a width of the other part thereof, whereby a slit 48 is formed between the connection guide portion and the connection guide portion of the other solar cell unit U.

The connection guide portions 47 are fixed as follows. The connecting/fixing fitting 31 is inserted in a manner that the upper member 36 and the lower member 37 clamp the connection guide portions 47 therebetween. Subsequently, the lugs 39a, 39b of the upper member 36 are inserted in the respective holes 46a, 46b.

The aforementioned slit 48 is a passage for the bolt 38 interconnecting the upper member 36 and the lower member 37 to pass therethrough.

Thereafter, as shown in FIG. 32, the bolt 38 is fastened thereby clamping and fixing the connection guide portions 47a, 47b between the upper member 36 and the lower member 37 at a time. Thus, the solar cell units Ua, Ub are rigidly interconnected.

Furthermore, the back-forth and lateral movements of the solar cell units Ua, Ub are constrained by the lugs 39a, 39b inserted in the holes 46a, 46b, so that the interconnection can be maintained even against such a great stress under which the mere clamping/fixing by fastening the bolt cannot retain the interconnection.

If the connection guide portions 47a, 47b are not positioned correctly during the installation works, it is impossible to insert the lugs 39a, 39b into the holes 46a, 46b. Therefore, the embodiment specifies a positional relation between the lugs 39a, 39b and the holes 46a, 46b. The connecting/fixing fitting 31 is mounted based on the positional relation thus specified, thereby achieving the correct positioning of the solar cell units U.

As shown in FIG. 32, the connecting/fixing fitting 31 is designed such that the connecting/fixing fitting clampingly fix the connection guide portions 47a, 47b while at the same time, the solar-cell pressing portion 34 thereof prevents the uplift of the solar cell units U.

This permits the upper side racks 101 and the lower side racks 102 to hold down the force to lift up the solar cell units U (the wind load) so that the load on the screw or the bolt of the connecting/fixing fitting 31 is reduced. Thus, the solar cell units U are further increased in the resistance against the wind load.

According to the embodiment, in addition, the connecting/fixing fittings used for fixing the individual members have a common configuration such that the fittings may be applied to all the fixing places. Accordingly, the number of components is notably reduced.

Furthermore, the connecting/fixing fitting has the bolt previously fitted with the nut or fitted the screw hole in the lower member 37 and in this state, the connecting/fixing fitting 31 is used, whereby human errors such as lost bolt, dropped bolt or difficult insertion of bolt may be reduced.

The foregoing is the explanation about the state of the photovoltaic power generation system wherein the four solar cell units U are arranged along the direction perpendicular to the direction of the placement of the racks and are interconnected.

However, it is also possible to arrange plural strings of solar cell units U along the direction of the placement of the racks, thereby accomplishing the matrix array of the solar cell units U.

FIG. 33 is an external perspective view showing a photovoltaic power generation system wherein solar cell units Ua to Uh are arranged in the matrix form.

To make the matrix array, the lower side rack 102b of the next solar cell unit U may be overlapped on a part of the upper side rack 101. Subsequently, the solar cell units U may sequentially be placed and interconnected and then, the weights 104 may be placed on the upper side racks 101 and the lower side racks 102. Thus is completed the photovoltaic power generation system as shown in FIG. 33.

In FIG. 33, the solar cell units Ua to Ud and the solar cell units Ue to Uh are interconnected and fixed, so that the uplift due to the wind load is resisted by way of the total weight of the solar cell units U. Hence, the system is adapted to withstand a greater wind load as compared with the case where the solar cell unit is singly installed.

By virtue of such a matrix array of the solar cell unit U, in particular, the solar cell units Ua to Ud are pressed down by the weight of the next string of the solar cell units Ue to Uh, whereby the resistance against the uplift due to the wind load or the like is increased.

The pair of opposing racks is not necessarily pressed down by the weight 104 having the same weight or the same configuration. Weights individually having different weights or configurations may be disposed on the rack on one side and the rack on the other side, respectively.

While the photovoltaic power generation system of the above embodiment is the photovoltaic power generation system wherein the solar cell units U are arranged in the matrix form and provided with the weights, an alternative construction may be made such that the weights are dispensed with.

Although the weights are not employed, the overall weight of the system is increased by arranging the plural solar cell units U along the direction perpendicular to the direction of the placement of the racks and further arranging the plural solar cell unit along the direction of the placement of the racks. This structure is adapted to hold down the solar cell units U and the like in a manner to ensure that the units and the like are not blown away by the negative pressure load due to wind or the like.

Connecting/fixing fittings according to other embodiments of the invention are described by way of the following examples.

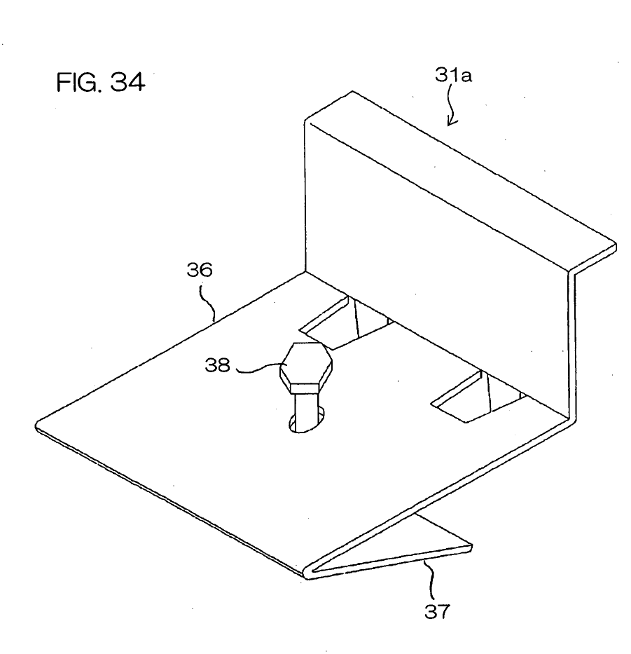

FIG. 34 is a perspective view of a connecting/fixing fitting 31a. The connecting/fixing fitting 31a includes the upper member 36 and the lower member 37 which are formed of one piece of metal sheet. The upper member 36 and the lower member 37 are integrally formed by folding one piece of metal sheet.

In this structure, the upper member 36 and the lower member 37 are not separated from each other and hence, the drop-off of the bolt 38, which is excessively loosened, is avoided. In addition, there is another advantage that the upper member 36 and the lower member 37 are not lost because they are not separate from each other.

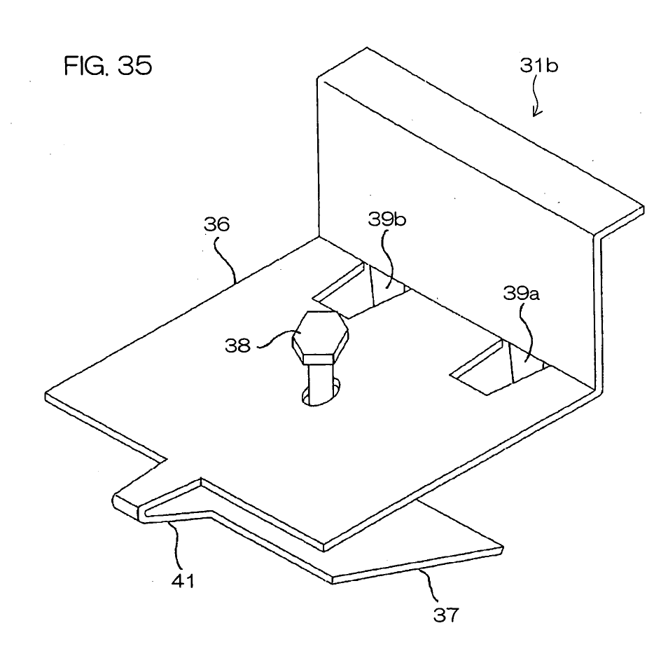

FIG. 35 is a perspective view of another connecting/fixing fitting 31b.

The connecting/fixing fitting 31b has a different structure from that of the connecting/fixing fitting 31a shown in FIG. 34 in that the upper member 36 and the lower member 37 are connected with each other via a partial bent portion 41.

According to this embodiment, a reaction force acting to expand the upper member 36 and the lower member 37 during the fastening of the bolt 38 is decreased so that a fastening torque may be reduced. As a result, the constructability is improved.

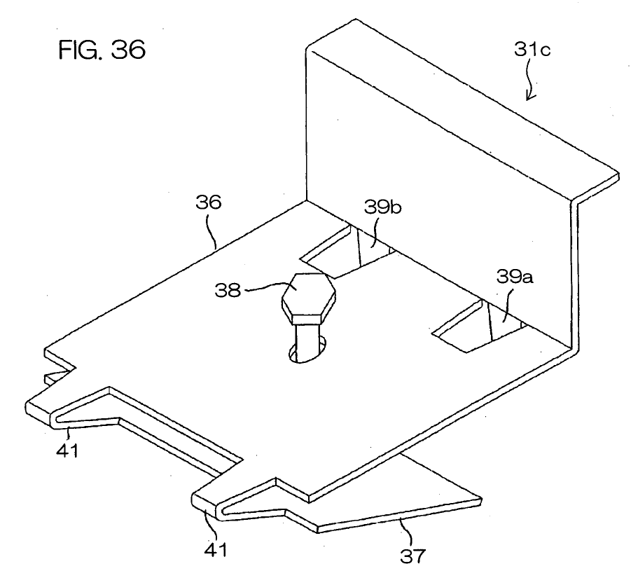

FIG. 36 is a perspective view of still another connecting/fixing fitting 31c.

The connecting/fixing fitting 31c has a different structure from that of the connecting/fixing fitting 31b shown in FIG. 35 in that the upper member 36 and the lower member 37 are connected with each other via two bent portions 41. By providing the two bent portions 41, these members are increased in the connecting strength and besides, the aforesaid reaction force is reduced. As a result, the constructability is further improved.

Next, description is made on a photovoltaic power generation system employing an air-inflow blocking member according to another embodiment of the invention.

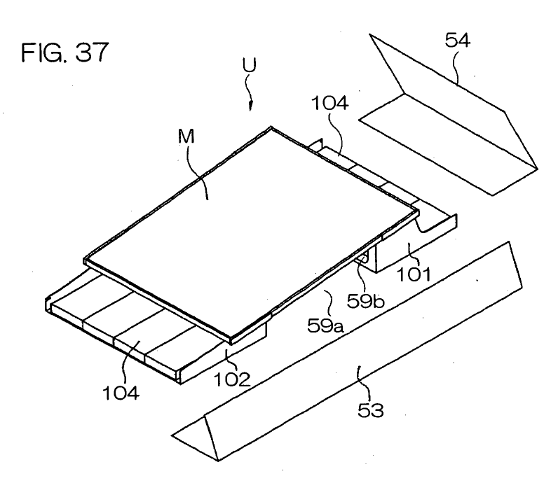

FIG. 37 is a perspective view showing a solar cell unit U comprising the assembly of the racks, the solar cell module M and the weights as the weight member.

As shown in FIG. 37, the solar cell unit U is provided with air-inflow blocking plates (wind guide plate, wind plate) 53, 54 in the vicinity thereof.

The solar cell unit U defines a space region allowing the air to flow into a ventilation path 59b of the upper side rack 101, a ventilation path 59b of the lower side rack 102 and a ventilation path 59a defined between the upper side rack 101 and the lower side rack 102. The air-inflow blocking plates 53, 54 are disposed around the solar cell unit U in a manner to block the air flow entering this space region.

Such air-inflow blocking plates 53, 54 function as the wind guide plate or the wind plate.

The air-inflow blocking plates 53, 54 employs a metal sheet such as aluminum or SUS, which is bent as shown in FIG. 37. However, the air-inflow blocking plate is not limited to the structure formed by bending the metal sheet but may be a molded article of ceramics or synthetic resin, a concrete block, or a metal block such as of iron. In short, the air-inflow blocking plate may have any shape or be formed from any material so long as the plate is able to reduce the quantity of wind into the ventilation paths 59a, 59b.

This solar cell unit U and the air-inflow blocking plates 53, 54 are installed on the flat roof or the like.

The air-inflow blocking plates 53, 54 are bonded to the installation surface on the roof using an epoxy-base, urethane-base or rubber-base bonding agent. In a case where the concrete block or the metal block such as of iron is used as the air-inflow blocking plates 53, 54, the fixing of the blocks is accomplished simply by placing the blocks. Hence, the constructability is improved.

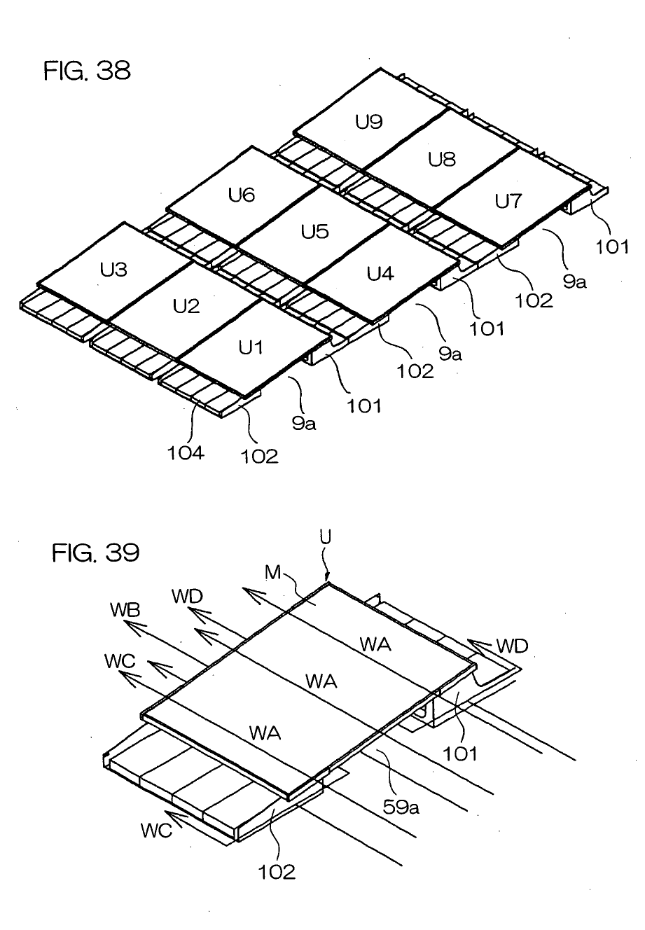

FIG. 38 is a perspective view showing a photovoltaic power generation system wherein a large number of solar cell units U are installed. A photovoltaic power generation system capable of providing a desired power output may be realized by installing, on the flat roof or the like, a plural number of photovoltaic power generation sub-system thus assembled.

Description is made on the flow of wind as below.

First, description is made only on the state of the solar cell unit U.

In FIG. 39, wind blowing from a lateral side of the solar cell unit U is represented by arrows.

As seen from the figure, the wind passes through various parts of the solar cell unit U in a manner to enclose the periphery of the solar cell unit U.

A wind flow WA passes over the surface of the solar cell module M, whereas a wind flow WB passes though the ventilation path 59a on the back side of the solar cell module M. Wind flows WC, WD are defined as follows. Wind hits against the lateral side of the racks 101, 102 so as to be branched into sub-flows, one of which passes through the ventilation path 59a to the opposite side of the solar cell module M, and the other of which passes by an outside end of the solar cell unit U to the opposite side thereof.

The wind flow WA moves at a higher level than the solar cell module M, principally providing drag (force pressing the solar cell module toward the installation surface). The wind flow WB moves at a lower level than the solar cell module M, principally providing lift (force lifting up the solar cell unit U).

This lift peaks at a windward corner of the solar cell unit U, thus providing a force lifting up the solar cell unit in a cantilever fashion. Accordingly, the solar cell unit U can be lifted up by a force smaller than the dead weight thereof. This is because the solar cell unit U lifted up several millimeters by the wind would allow the wind to enter a gap between the rack and the installation surface and to promote the lifting force further.

If a wind velocity of the wind on the windward side is equal to a wind velocity of the wind passing through the ventilation path 59a of the solar cell unit U, the resultant lift has a value most close to zero. However, every part of the solar cell unit U is normally exposed to the wind so that the wind velocity is decreased. Hence, pressure within the solar cell unit U is increased so that the lift is increased.

Similarly, the wind flows WC and WD are each divided into the drag and the lift. However, the wind flows WC and WD are diffused by the racks 101, 102 so as to provide a force too small to lift up the solar cell unit U.

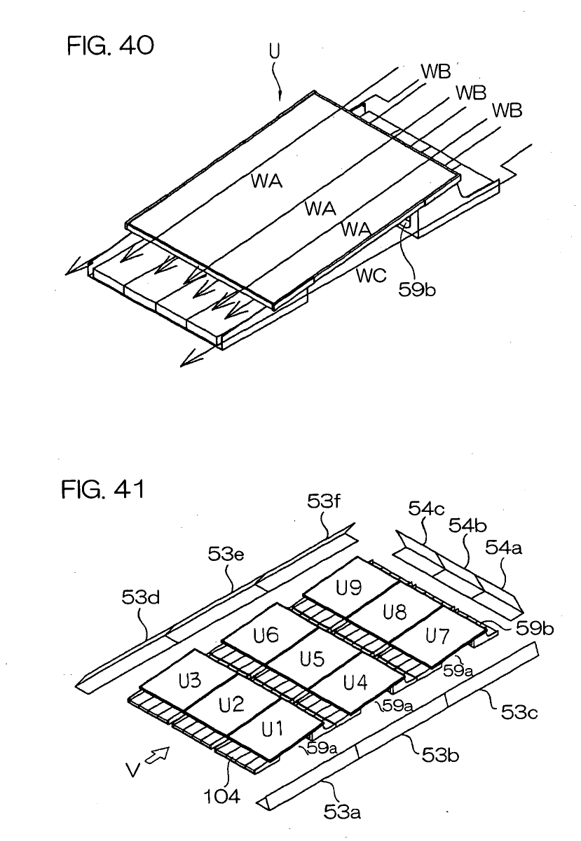

While the foregoing description pertains to the wind force generated at the solar cell unit U, a similar phenomenon is also caused by wind flows WA to WC from the shorter side of the solar cell unit U, as shown in FIG. 40.

In this case, the wind flow WB passing through the ventilation path 59b at the shorter side of the solar cell unit U has a significant influence.

In the case of the photovoltaic power generation system including the array of plural solar cell units U, as shown in FIG. 38, the generated wind lift varies depending upon the positions of the solar cell units U (U1 to U9).

This is because the wind passing through the ventilation path 59a of the windward solar cell unit U is at the maximum velocity, while the wind velocity is decreased each time the wind passage through the solar cell unit U. Assumed that the wind entering the ventilation path 59a of the solar cell unit U1 is at an initial velocity of, say, “10”, the wind slowed down in the solar cell unit U1 enters the solar cell unit U2 at a velocity of “8” and is further slowed down. The wind entering the next solar cell unit U3 has a velocity of “6”, which is substantially a half of the velocity of the wind entering the first solar cell unit U1. Thus, the wind lift is at maximum in the solar cell unit U1 whereas the wind lift is at minimum in the solar cell unit U3.

It is noted however that it is impossible to determine the direction in which the wind blows. Therefore, it is only in the solar cell unit U5 in the figure that the wind lift is decreased at all times.

On the other hand, the advantage of this phenomenon is taken so that the solar cell unit U5 subjected to the smaller lift may be provided with a weight 104 which is lighter than the weights 104 disposed at the solar cell units U1 to U4 and U6 to U9 located on the outermost circumference of the system. The weight reduction of the weight accordingly reduces the load on the roof. In addition, the weight reduction leads to a reduced number of steps of the installation works and to a higher degree of safety. This effect becomes more noticeable as the number of installed solar cell units U is increased.

Furthermore, as shown in FIG. 41, the air-inflow blocking plates 53, 54 (53a to 53f and 54a to 54f) are disposed on respective extensions from the individual ventilation paths 59a, 59b of the solar cell units U (U1 to U4 and U6 to U9) located on the outermost circumference of a solar cell array S, thereby providing effects to control the wind entering the ventilation paths 59a, 59b of the solar cell units U (U1 to U4 and U6 to U9) located on the outermost circumference, and to reduce the total weight of the whole body of the solar cell array S.

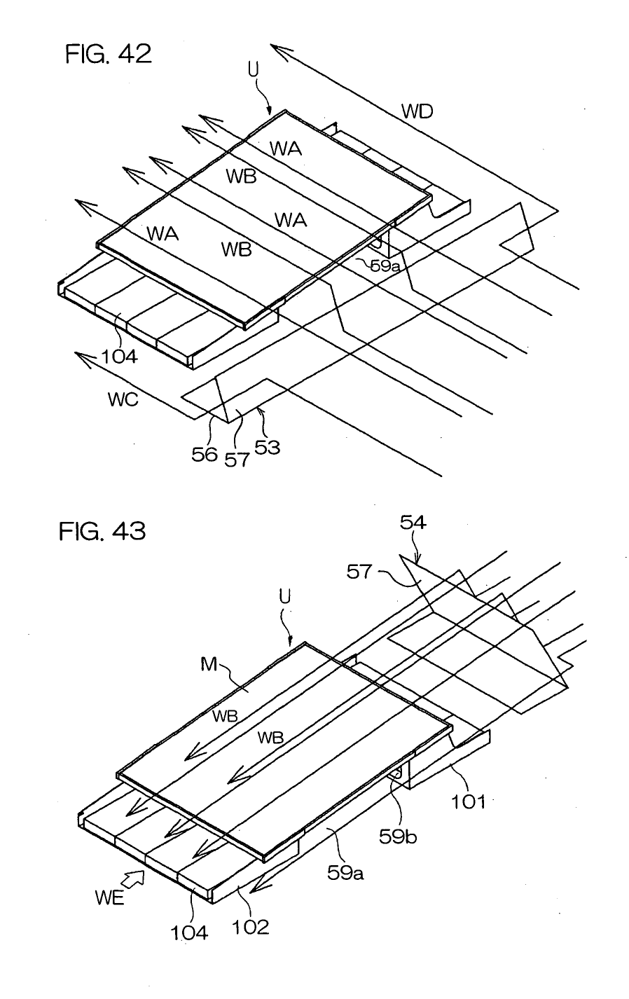

Now referring to FIG. 42 and FIG. 43, specific effects of installing the air-inflow blocking plate are described by way of example of a single solar cell unit U.

FIG. 42 is a perspective view showing the air-inflow blocking plate 53 disposed on a lateral side of the solar cell unit U.

The air-inflow blocking plate 53 comprises an installation plane 56 on which the air-inflow blocking plate 53 is fixed to the roof, and a wind guide plane 57 defined by a slant plane for guiding the wind flow in direction. The air-inflow blocking plate 53 is disposed at place on an extension from space in the ventilation path 59a as directing its longitudinal side substantially in parallel to an opening plane of the ventilation path 59a of the solar cell unit U.

The wind tends to move along a wall surface. The wind flow WB does not enter the ventilation path 59a of the solar cell unit U but is guided along the wind guide plane 57 of the air-inflow blocking plate 53 toward the surface of the solar cell unit U.

An experiment has revealed that wind flows, such as the wind flows WC, WD, hitting against places in the vicinity of the ends of the air-inflow blocking plate 53 are not guided along the slant plane of the air-inflow blocking plate 53 but are deflected away transversely of the air-inflow blocking plate 53.

In addition, a wind tunnel test has revealed that the air-inflow blocking plate 53 reduces the generated lift roughly by 30% as compared with a case where the air-inflow blocking plate 53 is not disposed. Therefore, the weight of the weight 104 may be reduced by an amount corresponding to the reduction of the lift.

FIG. 42 shows the air-inflow blocking plate 53 having the same length as the longitudinal length of the solar cell unit U. However, the air-inflow blocking plate may have a shorter length if the weight reduction of the weights 104 is not maximized.

On the other hand, the height and the angle of the wind guide plane 57 of the air-inflow blocking plate 53 are varied depending upon the height of the ventilation path 59a of the solar cell unit U and the wind velocity to be controlled.

FIG. 43 shows how the wind flow WB entering the ventilation path 59b of the solar cell unit U is controlled by the air-inflow blocking plate 54.

The solar cell module M is inclined in order to increase the efficiency of the power generation. Because of the inclination, the ventilation path 59b has its opening plane positioned at a higher level than that of the ventilation path 59a. Therefore, the air-inflow blocking plate 54 has its wind guide plane 57 positioned at a higher level than that of the air-inflow blocking plate 53.

The wind flow WB hitting against the air-inflow blocking plate 54 is guided by the wind guide plane 57 toward the surface of the solar cell unit U.

As to a wind flow WE entering from the lower side (lower side rack 102) of the solar cell unit U, it is not necessary to provide the air-inflow blocking plate 53. The reason is as follows. Because of the inclination of the solar cell unit U as described above, the ventilation path 59b on the upper side (upper side rack 101) has a wider opening area than the ventilation path 59b on the lower side (lower side rack 102) and hence, lift associated with the wind flow WE does not work.

Provided that the weights 104 disposed on the upper-side-rack 101 are heavy enough, an arrangement may be made wherein only the air-inflow blocking plate 53 is used while the air-inflow blocking plate 54 is dispensed with.

The foregoing description pertains to the solar cell unit U wherein the weight member (weights 104) is disposed at the racks. Alternatively, the solar cell unit U may also be arranged such that the weight member is dispensed with.

In the solar cell units U shown in FIG. 37 to FIG. 43, the weights 104 may be removed whereas the upper side rack 101 and the lower side rack 102 may be imparted with a function of the weight.

In practice, the rack may employ a heavy material such as metal. Otherwise, the rack may be increased in weight by increasing the volume thereof. In an alternative approach, the design of the material may be combined with the design of the volume of the rack to achieve this object.

In stead of bonding the air-inflow blocking plates 53, 54 to the installation surface on the roof using the bonding agent such as based on epoxy, urethane or rubber, many other various mounting methods may be adopted.

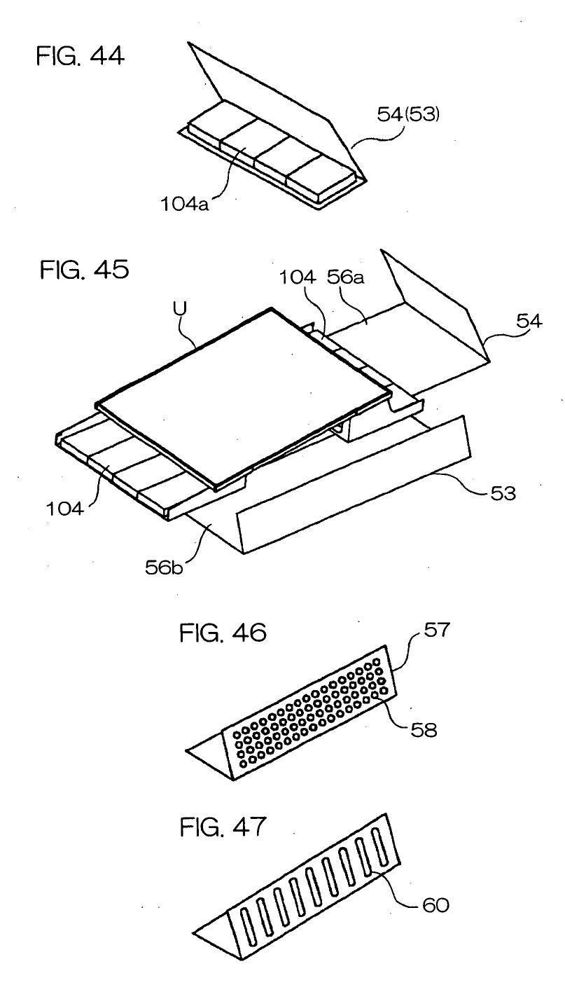

For instance, the air-inflow blocking plate may be fixed to place by way of the weight of small weights 104a, as shown in FIG. 44.

As shown in FIG. 45, an installation plane 56b of the air-inflow blocking plate 53 or an installation plane 56a of the air-inflow blocking plate 54 may be extended to place under the solar cell unit U so that the air-inflow blocking plate may be fixed to place by way of the dead weight of the solar cell unit U.

In an alternative design, the wind guide plane 57 may be formed with a plurality of air holes 58 as shown in FIG. 46 or with a plurality of slits 60 as shown in FIG. 47 such that the wind guide plane may not interfere with the passage of wind having a low force.

In the foregoing examples, the weight member is disposed on both of the racks on one side and on the other side. However, the weight member may be disposed only on either one of the racks.

While the structure of the air-inflow blocking plate defining the inclined wind guide plane is illustrated, the air-inflow blocking plate may have an alternative structure wherein the wind guide plane is not inclined but is extended substantially vertically. Such an air-inflow blocking plate has a function to block the air inflow and hence, is usable.

The disclosure of Japanese Patent Application Nos. 2004-021945, 2004-094015, 2004-185143, 2004-191747 and 2004-219777 filed on Jan. 29, 2004, Mar. 29, 2004, Jun. 23, 2004, Jun. 29, 2004, and Jul. 28, 2004, respectively, is incorporated herein by reference.

1. A photovoltaic power generation system comprising:
a rectangular- or square-shaped solar cell module including one or more solar cell elements;
first and second racks assembled to opposite sides of the solar cell module, respectively; and
a weight member disposed at a predetermined place of the first rack and/or the second rack.

2. A photovoltaic power generation system according to claim 1, wherein the first rack has a greater height than the second rack thereby to incline the solar cell module.

3. A photovoltaic power generation system according to claim 1, wherein the first rack and the second rack are each provided with a mounting member for insertion of the solar cell module.

4. A photovoltaic power generation system according to claim 3, wherein the mounting member includes: a guide having a function as an insertion guide for the solar cell module; and a pair of bent portions folded inwardly for fixing the inserted solar cell module to inhibit the back-forth movement thereof.

5. A photovoltaic power generation system according to claim 1, wherein the pair of the bent portions of the first rack and/or the second rack is bent at an angle smaller than 90°.

6. A photovoltaic power generation system comprising:
a plurality of solar cell units arranged along a direction of placement of racks of a solar cell module and/or a perpendicular direction thereof, the solar cell unit including a rectangular- or square-shaped solar cell module including one or more solar cell elements; and the racks assembled to opposite sides of the solar cell module,
the system further comprising a connecting member for interconnecting the racks of adjoining solar cell units.

7. A photovoltaic power generation system according to claim 6, wherein the rack includes a first rack and a second rack having a smaller height than the first rack,
wherein the connecting member interconnects the first rack of a solar cell unit and the second rack of a solar cell unit adjoining thereto.

8. A photovoltaic power generation system according to claim 7, wherein the second rack is formed with a first fit portion at an end thereof,
wherein the first rack is formed with a second fit portion an end thereof, and
wherein the connecting member includes a bent portion designed to clamp these interconnected first fit portion and the second fir portion in overlapped relation.

9. A photovoltaic power generation system according to claim 8, wherein the first rack, the second rack and/or the connecting member are formed from a conductive material and the racks are set at a substantially equal potential.

10. A photovoltaic power generation system according to claim 6, wherein a weight member is disposed at a predetermined place of the first rack and/or the second rack.

11. A photovoltaic power generation system according to claim 7, wherein the racks include a first rack and a second rack having a smaller height than the first rack, and
wherein the connecting member interconnects the respective first racks and/or the respective second racks of adjoining solar cell unit.

12. A photovoltaic power generation system according to claim 11, wherein each of the racks is formed with a connection guide portion,
wherein the connecting member includes an upper member, a lower member and a fastening structure for fastening these members with each other, and
wherein the upper member and the lower member are fastened with each other in a state where the connection guide portion is inserted between the upper member and the lower member.

13. A photovoltaic power generation system according to claim 12, wherein the connection guide portion is formed with a hole at a predetermined position, whereas the upper member is formed with a lug to be inserted in the hole formed in the connection guide portion.

14. A photovoltaic power generation system comprising:
a rectangular- or square-shaped solar cell module including one or more solar cell elements; and
racks assembled to opposite sides of the solar cell module, respectively,
wherein a space region allowing an air flow therein is present under the solar cell module, whereas an air-inflow blocking member for blocking the air flow into the space region is disposed in the vicinity of the space region.

15. A photovoltaic power generation system according to claim 14, wherein the air-inflow blocking member is provided with a slant plane for guiding an air flow toward the slant plane to flow over an upper side of the solar cell module.

16. A photovoltaic power generation system comprising: a plurality of solar cell units arranged along a direction of placement of racks of a solar cell module and/or along a direction perpendicular thereof, the solar cell unit including a rectangular- or square-shaped solar cell module including one or more solar cell elements; and the racks assembled to opposite sides of the solar cell module, respectively,
wherein a space region allowing an air flow therein is present under the solar cell module, whereas an air-inflow blocking member for blocking the air flow into the space region is disposed along the direction of the placement of the racks located in the vicinity of the space region.
